(19) United States
(12) Patent Application Publication
(10) Pub. No.: US 2015/0270431 A1
(43) Pub. Date: Sep. 24, 2015

(54) APPARATUS AND METHOD FOR PERFORMANCE RECOVERY OF LAMINATED PHOTOVOLTAIC MODULE

(71) Applicant: Stion Corporation, San Jose, CA (US)

(72) Inventors: Chester A. Farris, III, Yorba Linda, CA (US); Joseph Anderson, Hattiesburg, MS (US); James Henry Whittemore, IV, Hattiesburg, MS (US); Laila Dounas, San Jose, CA (US); Todd G. Brehmer, San Jose, CA (US); Robert D. Wieting, Simi Valley, CA (US)

(21) Appl. No.: 14/660,858

(22) Filed: Mar. 17, 2015

Related U.S. Application Data
(60) Provisional application No. 61/954,854, filed on Mar. 18, 2014.

(51) Int. Cl. H01L 31/18

(52) U.S. Cl. CPC H01L 31/186; H01L 31/1876

(57) ABSTRACT

A method and apparatus for recovering and stabilizing photovoltaic performance of a thin-film solar module after lamination. The method includes a LED light soaking treatment prior to a forward biasing treatment of the thin-film photovoltaic material formed on a glass panel. The apparatus for implementing the method comprises an in-line system for loading the laminated solar panel on a conveyor to pass through a first process station to allow a brief LED light illumination followed by disposing the same laminated glass panel in a second process station to receive a forward bias treatment including applying multiple short electrical pulses with a constant current through the thin-film solar module. The photovoltaic performance of the laminated thin-film solar module after these treatments is recovered to substantially a same level obtained in a bare-circuit configuration and is stabilized substantially free from being affected by any further long-time light soaking.

### CROSS-REFERENCES TO RELATED APPLICATIONS

This application claims priority to U.S. Provisional Patent Application No. 61/954,854, filed Mar. 18, 2014, commonly assigned, and hereby incorporated by reference in its entirety herein for all purpose.

### BACKGROUND OF THE INVENTION

The present invention relates generally to techniques for manufacturing thin-film photovoltaic module. More particularly, the present invention provides an apparatus and method for recovering output power partially lost due to lamination of thin-film photovoltaic modules. Merely by way of examples, an in-line process station is designated for implementing the method for treating laminated thin-film photovoltaic modules for effectively recovering and stabilizing module performance, but it would be recognized that the invention may have other applications.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking. Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells.

Many techniques have been applied to enhance the photovoltaic efficiency during the manufacture of solar modules based on both crystalline material and thin film material. Some techniques were also found to be effective even after the solar module was off the manufacture line. For example, as-manufactured thin-film solar module shows some performance level loss due to the lamination process. Accordingly, extended continuous illumination of the laminated solar module, the so-called light soaking effect, is found to be very useful technique for boosting both just-deployed and long-term out-door exposed module performance. For CIGS-based thin film solar cell, light soaking treatment shown in FIG. 1 has been used for re-establishing initial state of photoconductivity lost after the lamination process. Open-circuit voltage rises upon light exposure with corresponding rise in photovoltaic efficiency. In general, the light soaking effect is believed to be associated with a buffer layer of the CIGS solar cell. Particularly, at an interface between the CIGS absorber layer and the buffer layer a barrier for electrons is created, which inhibits transport of carriers from the CIGS absorber layer to the TCO Layer (Transparent Conducting Oxides) and to the outside circuit. This barrier can be lowered due to incoming photons that are absorbed in the buffer layer. Light soaking effect has been shown to produce 7-15% improvement in cell efficiency for CIGS-based solar module. However, while mechanisms behind the beneficial effect of light soaking are still debatable, the practice of light soaking treatment requires extended hours of post-manufacture time, either through outdoor sunlight or using specific light sources. This introduces many issues in module handling, storage, and on-field QC measurement and causes many undesired extra cost for the manufacture of thin-film solar modules.

Alternatively, an electrical biasing treatment method is proposed to stabilize module performance using forward-bias current injection rather than light exposure of (laminated) CIGS-based solar modules. A constant current of the forward bias is set to the peak power current Iₘₚ of the solar module for treating the laminated module continuously for about an hour or so, after which the module's performance is partially recovered and varied less than 3%. However, this method is just aimed for relieving extended time requirement for staging the modules in a solar simulator immediately after they are brought indoors after sun-soaking Even though it may be used to replace conventional light soaking treatment to some degrees, it still lacks manufacturability due to the fact of long biasing process time of nearly an hour or so and less pronounced recovery in module performance than using conventional sun light soaking treatment.

Therefore, it is highly desired to have an improved method for treating the laminated thin-film solar modules for achieving same effect expected for long-time sun light soaking treatment with substantially reduction in process time and energy usage. It is also an objective of the present invention to have an apparatus with automation for handling high volume production of thin-film solar panels for implementing the method with substantially enhanced manufacturability.

### BRIEF SUMMARY OF THE INVENTION

Embodiments of the present invention are generally related to techniques for manufacturing thin-film photovoltaic module. More particularly, an apparatus and method are provided for treating laminated photovoltaic modules for quick performance recovery. Merely by way of examples, an in-line multi-panel process station is designated for implementing the method for applying a brief LED light soaking treatment and several short pulsed forward electrical biasing treatment to the laminated thin-film photovoltaic modules for effectively recovering and stabilizing module performance, but it would be recognized that the invention may have other applications.

In a specific embodiment, the present invention provides a method for recovering and stabilizing output power of a thin-film solar module after lamination. The method includes providing a thin-film solar module in a bare-circuit configuration formed on a front side of a glass panel and obtaining a first performance data associated with the thin-film solar module in the bare-circuit configuration. Additionally, the method includes laminating the glass panel into a frame to form a thin-film solar module in a laminated configuration with a j-box containing two electrical leads of the thin-film solar module mounted on a back side of the glass panel. The method further includes obtaining a second performance data associated with the thin-film solar module in the laminated configuration. Furthermore, the method includes exposing the front side of the laminated glass panel to LED light for a first predetermined time and coupling a power supply with the two electrical leads to form a bias circuit through the thin-film solar module in the laminated configuration. Moreover, the method includes performing multiple cycles of a forward biasing treatment via the bias circuit to the thin-film solar module in the laminated configuration. Each cycle starting with using the power supply to apply a forward bias voltage sufficient to yield a current at a set value substantially free from current ramping while adjusting the forward bias voltage to keep the current to be constant at the set value till a second predetermined time followed by turning off the power supply for a third predetermined time. The method also includes obtaining a third performance data associated with the thin-film solar module in the laminated configuration after the forward biasing treatment. The third performance data is nearly the same as or better than the first performance data and substantially not affected by any further light soaking of the thin-film solar module in the laminated configuration.

In another specific embodiment, the invention provides an apparatus for treating a plurality of solar panels after lamination process for recovering and stabilizing photovoltaic performance. The apparatus includes a loading conveyor configured to transfer a plurality of laminated solar panels one after another. Each laminated solar panel includes a front side formed with a photovoltaic absorber material and a back side mounted with a j-box having two electrical leads. The apparatus further includes a first process station enclosing a section of the loading conveyor. The first process station includes a 2D array of LED emitter devices disposed across the entire section to provide luminous flux onto the front side of the laminated solar panel passed by. Additionally, the apparatus includes an input elevator configured to hold one of the plurality of laminated solar panels received from the lading conveyor and navigate multiple height levels from number 1 to number N where N is an integer greater than one. The apparatus further includes a second process station comprising multiple slots from number 1 to number N respectively leveled with the corresponding multiple height levels of the input elevator. Each slot is configured to receive one laminated solar panel from the input elevator at a time. Furthermore, the apparatus includes a power rack station comprising multiple power supplies. Each power supply is configured to couple with the two electrical leads in the j-box of the laminated solar panel loaded in the corresponding one of multiple slots of the second process station and to apply multiple forward bias voltage pulses with constant current through the laminated solar panel. The apparatus further includes an output elevator configured to navigate the multiple height levels for picking up one laminated solar panel from the corresponding slot of the second process station. Moreover, the apparatus includes an unloading conveyor configured to receive the laminated solar panel from the output elevator and deliver away the laminated solar panel.

In yet another specific embodiment, the invention provides a method for processing a thin-film solar module after lamination. The method includes loading a thin-film solar module on a conveyor. The thin-film solar module is on a laminated glass panel having a front side formed with a photovoltaic absorber material and a back side mounted with a j-box having two external electrical leads of the thin-film solar module. The method also includes moving the laminated glass panel along the conveyor into a first process station having an array of LED emitter devices installed therein. Additionally, the method includes exposing the photovoltaic absorber material on the entire front side to light provided from the array of LED emitter devices for a first predetermined time as the laminated glass panel continues to move along the conveyor. The method further includes transferring the laminated glass panel from the first process station to a loading elevator configured to navigate multiple height levels and loading the laminated glass panel into a second process station from the loading elevator. The laminated glass panel is disposed in a selected slot that is leveled with one of the multiple height levels of the loading elevator. Furthermore, the method includes coupling a power supply with the two electrical leads in the j-box mounted on the back side of the laminated glass panel in the selected slot to form a bias circuit through the thin-film solar module. The method then includes performing multiple cycles of forward biasing treatment to the thin-film solar module via the bias circuit. Each cycle starts with using the power supply in a constant current mode to apply a forward bias voltage pulse at a sufficiently large value to yield a current at a desired set value while adjusting the voltage to keep the current to be constant at the desired set value till a second predetermined time followed by turning off the power supply for a third predetermined time. Moreover, the method includes unloading the laminated glass panel from the second process station to the conveyor via an unloading elevator capable of navigate the same multiple height levels.

Many benefits can be achieved by applying the embodiments of the present invention. The present invention provides a method for using a much shortened LED light soak treatment followed by an simplified electrical biasing treatment to replace a time-consuming sun-soaking process for not only recovering dark storage module efficiency loss but also enhancing the module performance by 7-15% from a after-lamination state. In particular, an embodiment of the present invention provides an improved technique for treating the laminated thin-film solar modules by applying well designed LED 2D arrays to quickly illuminate the front side containing the photovoltaic absorber. With just 3 to 5 minutes LED light soak, many fast acting transient recombination sites within the p-type thin-film photovoltaic absorber material are repaired and the film resistance is greatly reduced from the just-laminated status. Further, an open-circuit forward biasing voltage in constant current mode can be applied in subsequent steps to the two electrical leads of the solar module for further repairing majority of the remaining defects in the film. As the film resistance is reduced by LED light soak, the forward electrical biasing treatment becomes much more efficient by passing the current directly through the semiconducting film instead of mainly through the conductive shunts. One major benefit of the present invention is to substantially cut process time from a few hours for using sunlight-soaking technique to less than 10 minutes by using the LED soak plus forward biasing while substantially recovering and stabilizing the cell efficiency after lamination. These and other benefits may be described throughout the present specification and more particularly below.

### BRIEF DESCRIPTION OF THE DRAWINGS

FIG. 1 is a schematic diagram showing a light soaking treatment applied to CIGS-based thin-film solar cells in prior art;

FIG. 2A is a diagram showing comparison of performance efficiency of sample modules under a light soaking treatment versus a forward biasing treatment according to an embodiment of the present invention;

FIG. 2B is a diagram showing comparison of module efficiency gain after a light soaking treatment versus after a forward biasing treatment according to the embodiment of the present invention;

FIG. 3A is a diagram showing comparison of photovoltaic efficiency of sample modules under a light soaking treatment versus a forward biasing treatment according to another embodiment of the present invention;

FIG. 3B is a diagram showing comparison of module efficiency gain after a light soaking treatment versus after a forward biasing treatment according to the embodiment of the present invention;

FIG. 4A is a diagram showing additional improvement of module performance using forward biasing treatment according to yet another embodiment of the present invention;

FIG. 4B is a diagram showing additional module efficiency gain using forward biasing treatment according to the embodiment of the present invention;

FIG. 5 is a diagram showing maximum power changes of laminated thin-film solar modules from an initial (no light-soaking) state after lamination through a short-time biasing treatment followed by 2-hour sun soaking treatment according to an embodiment of the present invention;

FIG. 6 is a diagram showing maximum power changes of laminated thin-film solar modules from an initial (no light-soaking) state after lamination through one or more short-time biasing treatments followed by 2-hour sun soaking treatment according to another embodiment of the present invention;

FIG. 7 is a diagram showing comparison of maximum power change of laminated thin-film solar modules from an initial (no light-soaking) state after lamination through a short continuous biasing treatment vs. two short pulsed biasing treatment followed by 2-hour sun soaking treatment according to another embodiment of the present invention;

FIG. 8A is a diagram showing a bivarite fit of module maximum power data for laminated modules with a 5-minute light soaking treatment versus previous bare-circuit modules according to an embodiment of the present invention;

FIG. 8B is a diagram showing a bivarite fit of module maximum power data for laminated modules with a 2-hour sun soaking treatment versus previous bare-circuit modules according to another embodiment of the present invention;

FIG. 8C is a diagram showing a bivarite fit of module maximum power data for laminated modules with a forward biasing treatment after the 5-minute light soaking treatment versus previous bare-circuit modules according to yet another embodiment of the present invention;

FIG. 8D is a diagram showing a bivarite fit of module maximum power data for laminated modules with a forward biasing treatment only versus previous bare-circuit modules according to yet still another embodiment of the present invention;

FIG. 9 is a diagram of a I-V profile of two laminated thin-film solar panels under a forward biasing treatment without any prior LED light soaking according to an embodiment of the present invention;

FIGS. 10A and 10B are diagrams showing effectiveness of forward biasing versus sun soaking as a method for recovering solar panel lamination loss according to an embodiment of the present invention.

FIGS. 11A and 11B are two diagrams showing effectiveness of using forward biasing with or without a prior LED light soak treatment on panel lamination performance recovery according to a specific embodiment of the present invention.

FIG. 12 is a diagram of a I-V profile of two laminated thin-film solar panels under a forward biasing treatment with a prior LED light soaking according to an embodiment of the present invention;

FIG. 13 is a chart showing a method for enhancing and stabilizing photovoltaic performance of a thin-film solar module after lamination according to an embodiment of the present invention.

FIG. 14 is a schematic diagram showing an apparatus for treating a group of laminated thin-film solar panels for recovering and stabilizing module performance according to an alternative embodiment of the present invention;

FIG. 15 is chart showing a method for using the apparatus (shown in FIG. 14) to treat the laminated thin-film solar panels for recovering and stabilizing module performance according to an alternative embodiment of the present invention.

FIG. 16A is a chart illustrating the use of a UV treatment according to embodiments of the present technology.

FIG. 16B is another chart illustrating the use of a UV treatment according to embodiments of the present technology.

FIG. 17A illustrates a top plan view of an exemplary UV treatment station according to embodiments of the present technology.

FIG. 17B illustrates a side view of an exemplary UV treatment station along line A-A of FIG. 17A according to embodiments of the present technology.

### DETAILED DESCRIPTION OF THE INVENTION

The present invention relates generally to techniques for the manufacture of photovoltaic devices. More particularly, the present invention provides a method for enhancing and stabilizing photovoltaic efficiency of as-fabricated solar module. Merely by way of examples, the present method is implemented using a time-saving and energy saving LED light soaking plus forward electrical biasing treatment of laminated thin-film photovoltaic modules and effectively enhancing and stabilizing photovoltaic efficiency, but it would be recognized that the invention may have other applications.

Light-to-dark metastable changes in thin-film photovoltaic modules often cause degradation of the module performance. CIGS modules improve their efficiency after being subjected to illumination which is known as light soaking effect. The extent and time dependence of the light soaking effect depends primarily on the dose of certain spectrum of light (part of sun light or specifically installed light source) that the module receives and the initial state of buffer layer between the CIGS absorber and conductor layer as well as the nature of defect/impurity doped into the buffer layer. This means that some modules need more photo doping through light soaking to achieve the ideal heterojunction conditions, while others are highly doped from the start and respond less to light soaking Variations in CIGS band gap and the thickness of the buffer layer also play an important role in how quickly the light soaking effect improves the module performance.

However, light soaking process always is a cumbersome and very time consuming one for manufacturing thin-film solar modules. An alternative method is to use forward bias current injection for the transient period when the modules are removed from sun-soaking status to in-door storage (shipping container) status for recovering the metastable change-caused module degradation and stabilizing the module performance up to a much longer (say 100 hours) time. With the forward-biasing method, the modules were maintained at their maximum Iₘₚ value while keeping a variable forward bias voltage for a period of time up to 1 hour by a power supply. The stabilized maximum power Pₘₚ of the modules under the forward bias was within 3% of the final outdoor-deployed Pₘₚ measurement. But, this conventional forward biasing method is still not sufficient or not efficient enough as a last step for manufacturing a thin-film solar module after its lamination to set its performance condition to a level that would be expected after some time out in the sun. The present invention provides a much efficient electrical pulse biasing method for fully replacing the time-consuming light (or sun) soaking process for the laminated thin-film solar modules to maintain and even improve the module performance level above the level that would be expected when they are installed in the field. As described below, through some experiments the electrical pulse biasing method is developed with variations in current value, bias condition settings, and pulse and rest period settings, etc.

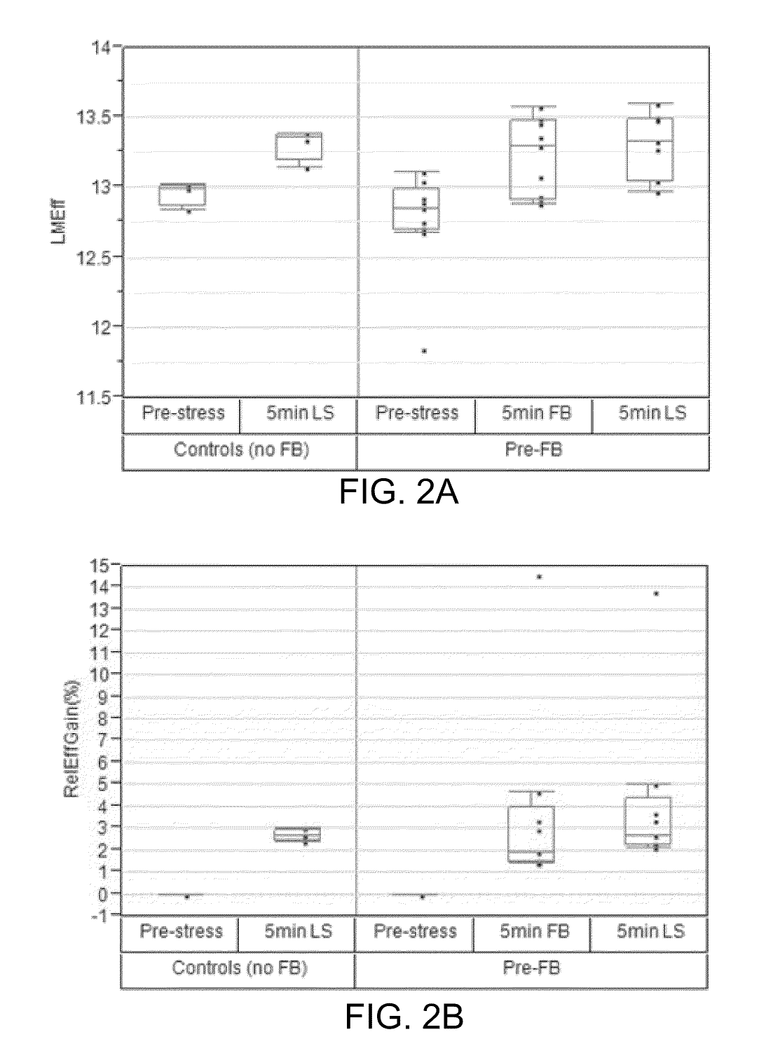

FIG. 2A is a diagram showing comparison of performance efficiency of sample modules under a light soaking treatment versus a forward biasing treatment according to an embodiment of the present invention. This diagram is merely an example, which should not unduly limit the scope of the claims herein. As shown in a specific embodiment, an electric pulse biasing pre-treatment is selected prior a 5-minute light soaking (representing a standard process) to use a power supply with 3 Amp current set and maximum voltage allowed for 5-minute duration. The process is compared to a control group that is treated with the standard process only (represented by the 5-min. light soaking) The sample modules used in these experiments are CIGS-based thin-film solar modules. Each module is individually laminated including >100 stripe-shaped cells connected in series within the same module panel. The result indicates that the 5-minute biasing treatment has raised the module efficiency from around 12.7% to about 13.3%, substantially equivalent to the effect of 5-minute light soaking treatment. The 5-minute light soaking treatment after the 5-minute forward biasing with 3 Amp current injection does not change the module efficiency that much. FIG. 2B, in the same embodiment, shows a diagram of comparison result of module efficiency gain after a light soaking treatment versus after a forward biasing treatment. It again suggests that the pre-forward biasing treatment can be potentially used to replace the light soaking treatment, at least up to the same time duration, although the data is a little scattered. Further refinement of the electrical pulse biasing method can be found throughout the present specification and more particularly below.

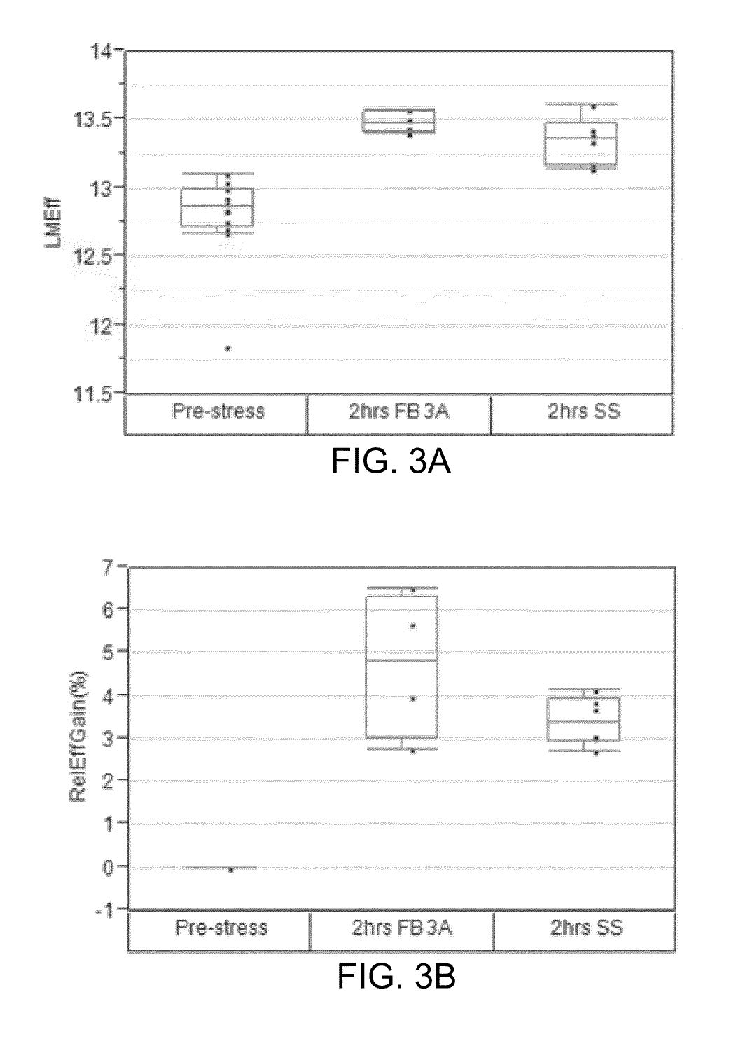

FIG. 3A is a diagram showing comparison of photovoltaic efficiency of sample modules under a light soaking treatment versus a forward biasing treatment according to another embodiment of the present invention. This diagram is merely an example, which should not unduly limit the scope of the claims herein. As shown in another specific embodiment, the electrical forward biasing treatment is set to be a continuous biasing at 3 Amp current injection through a laminated solar module for two hours of time. Compared to pre-treatment data, the (laminated) module efficiency is raised from an average 12.7% to 13.5% after the electrical forward biasing treatment, indicating a good recover of the module performance from a pre-stressed state of the as-manufactured CIGS-based thin-film solar modules. This corresponds to an efficiency gain percentage up to 7%, as shown in FIG. 3B in the same embodiment. Two hours of continuous biasing treatment time is sufficiently longer than 5 minutes pulse used in last embodiment. After the biasing treatment, the same samples are further treated using sun light soaking for 2 hours. The resulted (laminated) module efficiency values and real gains over the pre-stressed state are shown in FIGS. 3A and 3B, respectively. It shows that the sun soaking after electrical biasing basically causes no further change or additional gain to the module efficiency performance level within a certain variation margin. In other words, the application of the 2-hour electric biasing treatment may have substantially achieved the recovery of the metastable reversible performance change of the solar modules and stabilized the efficiency at least to a level corresponding to what is expected for the modules after 2-hour sun light soaking.

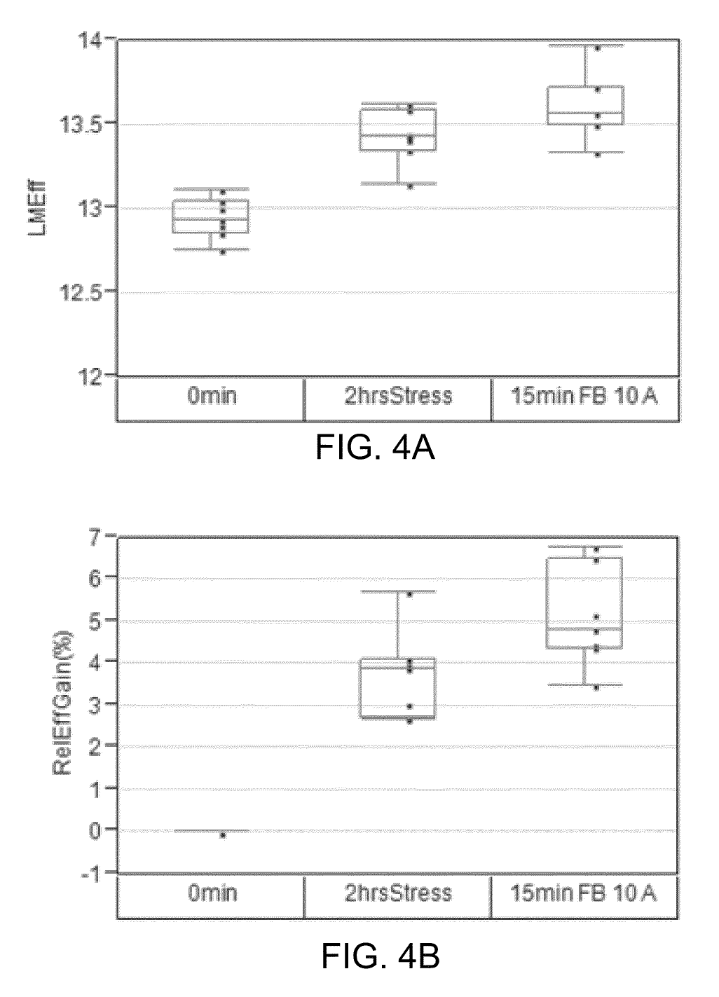

Based on the description in above embodiment (FIGS. 3A and 3B), the module performance level (in terms of photovoltaic efficiency) after 2-hour sun soaking treatment or the 2-hour sun soaking after 2-hour electrical biasing at 3 Amp current injection has been substantially stabilized as the 2-hour sun soaking did not change further the performance level. In another specific embodiment, FIGS. 4A and 4B show that the effect of additional electrical forward biasing treatment with 10 Amp current injection through laminated solar modules after 2-hour sun soaking treatment is conducted for the sample modules used in FIGS. 3A and 3B. As shown, another 15-minute forward biasing at 10 Amp current injection treatment is added for the same group of sample modules after the sun soaking treatment in last embodiment, showing additional improvement of module performance in terms of photovoltaic efficiency. FIG. 4A shows that the laminated module efficiency value increases from slightly below 13.5% to about 13.7% in average, which is a percentage gain of about 1% (final value is about 5-6% over the non-stressed samples) as shown in FIG. 4B. This suggests that the electrical biasing treatment with higher current injection value has even stronger effect to recover the metastable reversible change associated with the buffer layer defect doping next to the CIGS absorber layer. The method as shown as the embodiments above provides a process not only to stabilize the performance loss of thin-film solar module due to the CIGS device metastability after module lamination but also maybe to improve the module performance level beyond that expected from the conventional sun soaking treatment.

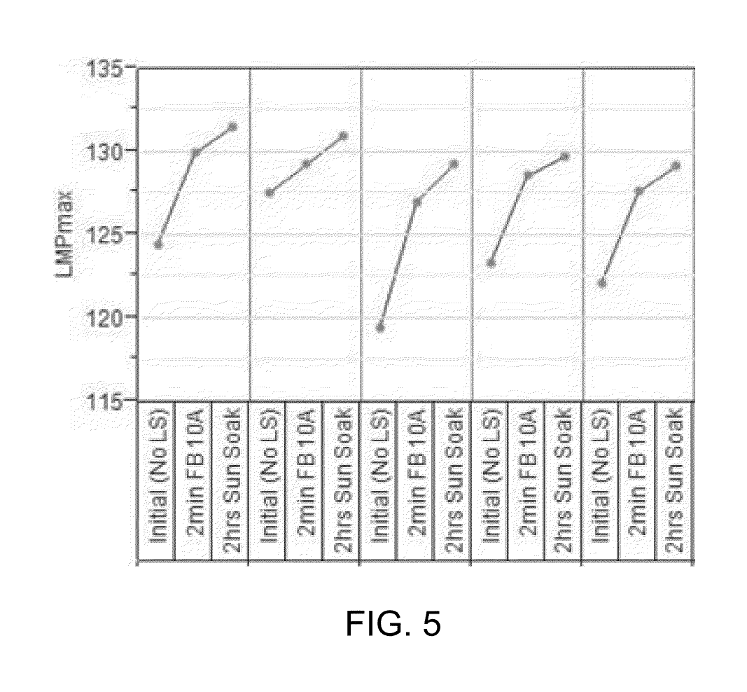

It has been demonstrated that 10 Amp current setting in the electrical biasing treatment is better than 3 Amp current setting in recovering performance loss due to the metastable change of CIGS-based thin-film solar module and improving the performance level over conventional sun soaking treatment. It is further desirable to reduce the process time of the electrical biasing treatment as a process to replace the light soaking treatment of the just-laminated solar module. FIG. 5 is a diagram showing maximum power changes of thin-film solar modules from an initial (no light-soaking) state after lamination through a short-time biasing treatment followed by 2-hour sun soaking treatment according to an embodiment of the present invention. As shown, the electrical biasing is respectively applied to five selected thin-film solar panels for just short 2 minutes of duration time with a constant current set at 10 Amp while allowing maximum forward voltage to change as the current injection takes place through the CIGS-absorber junctions of these sample solar panels. Following that a 2-hour sun soaking treatment is applied for each of these solar panels for evaluating the result of the shortened electrical biasing treatment.

Referring to FIG. 5, for all five samples of thin-film solar panels the sun soaking treatment clearly causes changes in terms of maximum output power after lamination. This indicates that the short 2-minute forward biasing with 10 Amp current setting seems not enough for achieving the desired performance level. The 2-hour sun soaking treatment on average causes additional 3 W power enhancement.

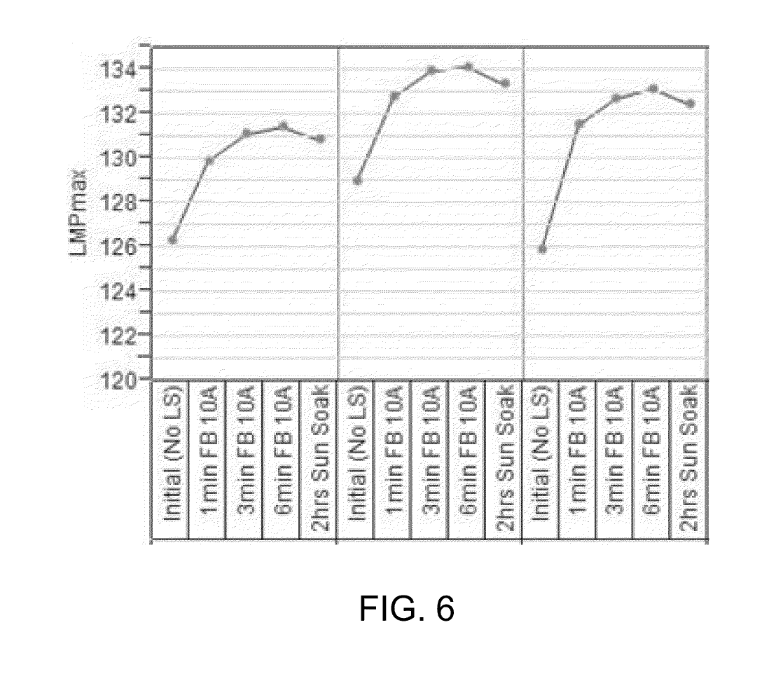

FIG. 6 is a diagram showing maximum power changes of thin-film solar modules from an initial (no light-soaking) state after lamination through one or more short-time biasing treatments followed by 2-hour sun soaking treatment according to another embodiment of the present invention. In the embodiment, there short-time electrical biasing treatments are applied for three thin-film solar modules before a 2-hour sun soaking treatment. The performance of the laminated modules is evaluated using its maximum output power Pₘₐₓ. The first short-time biasing treatment is a 1-minute forward biasing at 10 Amp. The second one is 3-minute forward biasing at 10 Amp. The third one is 6-minute forward biasing at 10 Amp. In an embodiment, the three short-time biasing treatments are performed consecutively equivalent to a 10-minute forward biasing treatment. In another embodiment, the three biasing treatments are respectively separated by a rest time, equivalent to three pulsed biasing treatments. As shown, after the third electrical biasing treatment is applied, the performance level reaches a peak for each of the three modules. Further 2-hour sun soaking treatment cannot bring the performance level higher, instead, it becomes slightly lower. This suggests that when the treatment time for electrical forward biasing is more than 10 minutes may not be effective anymore. The optimum time for short continuous biasing treatment (with 10 Amp current injection) could be just <10 minutes. It also suggests that the electrical biasing treatment may be effective by using one or more pulsed biasing treatments to replace a longer continuous treatment. Of course, there can be other variations, alternatives, and modifications.

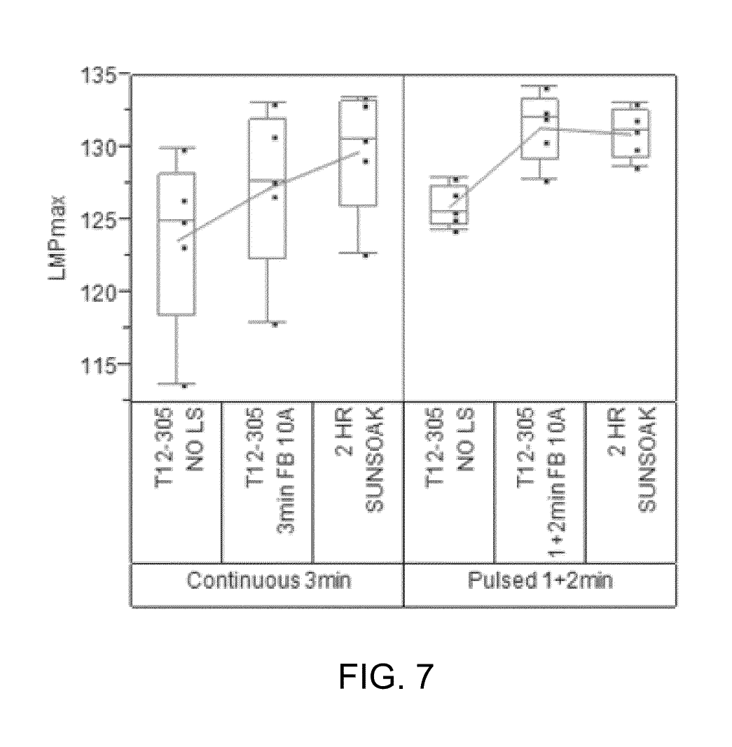

For further demonstrating the effectiveness of the pulsed biasing treatment over continuous biasing treatment, a comparison experiment is performed. FIG. 7 is a diagram showing comparison of maximum power change of a laminated thin-film solar module from an initial (no light-soaking) state after lamination through a short continuous biasing treatment vs. two short pulsed biasing treatment followed by 2-hour sun soaking treatment according to another embodiment of the present invention. This diagram is merely an example, which should not unduly limit the scope of the claims herein.

As shown in FIG. 7, in a first embodiment, the electrical biasing treatment applied for a group of five samples of laminated solar modules is conditioned to be a 3-minute continuous 10 Amp current injection associated with a variable maximum-allowed forward bias voltage. After the biasing treatment, the five samples of solar modules are further treated with sun soaking for 2 hours to evaluate the effect of biasing treatment. Apparently, based on the measurements of maximum output module power the 3-minute continuous electrical biasing treatment still does not lead to stabilization (or a saturated state) of the module's performance level as further enhancement is found by post-biasing sun soaking treatment. On the other hand, in a second embodiment the biasing treatment is conditioned as an one-plus-two pulsed biasing application with a rest time (<1 minute) in between. A first 1-minute pulsed biasing treatment with 10 Amp current injection is followed, after the rest time, by a second 2-minute pulsed biasing treatment with 10 Amp current injection. The total biasing time is the same of 3 minutes. As shown, the maximum laminate module power is substantially saturated to around 130 W that is basically not changed further by post-biasing 2-hour sun soaking treatment applied to the same five sample modules. This demonstrates that two or more short-pulsed electrical biasing treatments have a more pronounced effect than just a single continuous biasing treatment to recover and stabilize the thin-film module performance level to what should be expected using long-time light or sun soaking Of course, there are still some variations, alternatives, and modifications.

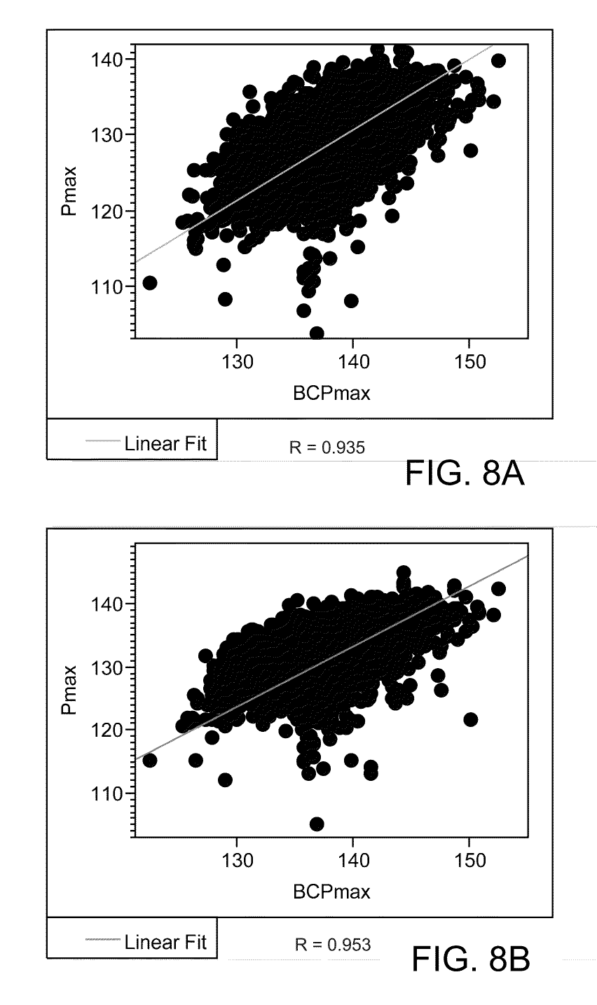

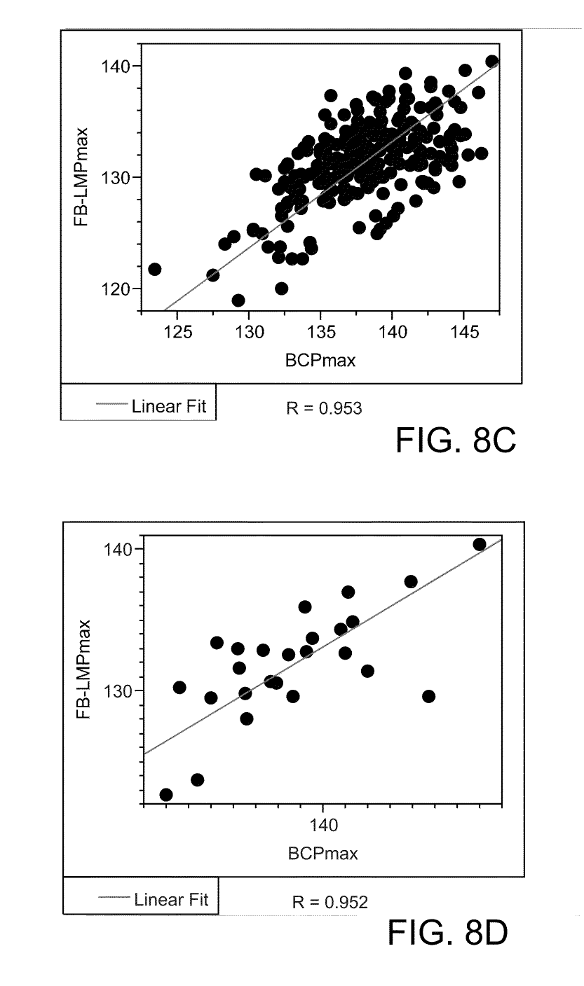

Additionally, the electrical biasing treatment method is explored by using much higher current setting while reducing the bias time shorter to achieve the same or even better effect for recovering and stabilizing thin-film solar module performance after lamination. In an embodiment, a high-power constant current power supply with maximum current setting up to 50 A is used. For example, in one preferred embodiment, a bias condition with 38 Amp current setting with the max voltage allowed is used for performing a short 30 seconds biasing treatment. FIGS. 8A through 8D are results recorded for four different treatments of a plurality of sample modules. All measured data of maximum laminate module power for sample modules with a certain treatment are plotted against the bare circuit maximum power data for the same sample modules. A variance analysis is carried to deduce a correlation between the two sets of measurement data. A linear fit yields a slope which represents a recovery ratio of the module performance in terms of laminate maximum power from initial bare circuit maximum power. As shown in FIG. 8A, the treatment applied to the laminated modules is a 5-minute light (in-door) soaking treatment. The recovery ratio for this treatment is about 0.935. In FIG. 8B, the treatment applied to the laminated modules is a 2-hour sun soaking treatment. The resulted recovery ratio is about 0.953. In FIG. 8C, the treatment is a 30-second pulsed forward biasing with 38 Amp current applied after the 5-minute light soaking treatment, and the associated recovery ratio is also about 0.953. In FIG. 8D, the treatment is the preferred 30-second pulsed biasing only, and the corresponding recovery ratio is 0.952, which is substantially the same effect as the 2-hour sun soaking treatment or the biasing plus light-soaking treatment. This indicates that the proposed 30-second pulsed biasing treatment is capable of replacing the 2-hour sun-soaking treatment to recover the lost performance level of the laminated thin-film solar module from initial bare-circuit state, although on average none of these treatments is able to recover the performance fully or even above the initial level.

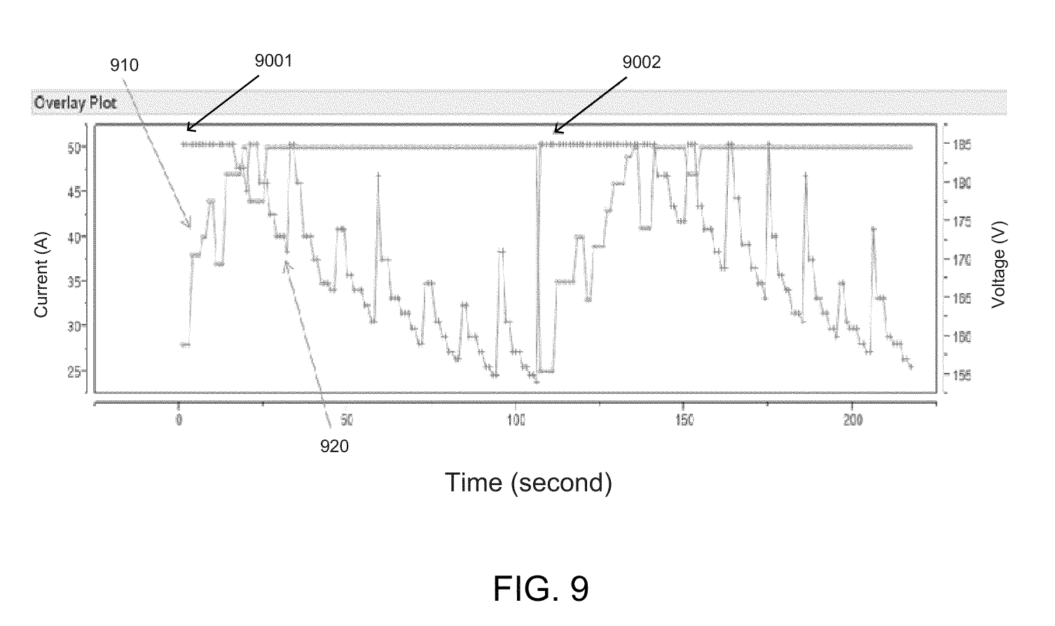

FIG. 9 is a diagram of an electrical biasing I-V profile applied on two thin-film solar panels without prior LED exposure according to an embodiment of the present invention. This diagram is merely an example, which should not unduly limit the scope of the claims herein. As shown, respectively for each thin-film solar panel after lamination a pulsed forward bias is applied to two electrodes across the p-n junctions of all cells within the solar panel based on a proposed procedure as specified below. For the first sample 9001, the pulsed biasing treatment starts a first pulse (10 sec.) using a power supply set in constant current mode. A bias voltage 920 is applied with a maximum value of 185 V and an output current 910 is ramped up to a nominal value less than 50 Amp depending on corresponding bias voltage and varies for individual panel. The pulse time is of 10 seconds. Then a rest period takes 30 seconds, during which both the current 910 and bias voltage 920 will drop to zero (but not shown in the plot) before a second pulse cycle starts. Every later pulse is following the similar cycle with a current value being ramped to a higher value until it reaches the maximum 50 Amp value (associated with the set 185 V bias voltage). The rest time is 30 seconds from one pulse to another in one embodiment and can be just 10 seconds in another embodiment. It should be pointed out that the rest time does not explicitly shown in the diagram (FIG. 9). Once the current 910 reaches max 50 Amp, the power supply adjusts the bias voltage 920 to set the current 910 to 50 Amp under current control. The bias voltage 920 for each pulse, as plotted in the diagram, peaks at every starting time of each pulse and drops as the bias time lapses within each pulse. Total number of pulses can be 5, 6, or up to 10 depending on embodiments. The second sample can start the 10-pulse biasing treatment 9002 after the 10th pulse ends with the first sample. Without prior LED soak treatment before biasing, final voltages are limited to maximum 185V and the first two bias cycles are consumed (likely due to conduction mainly through the shunts) with the limited voltage level while ramping current.

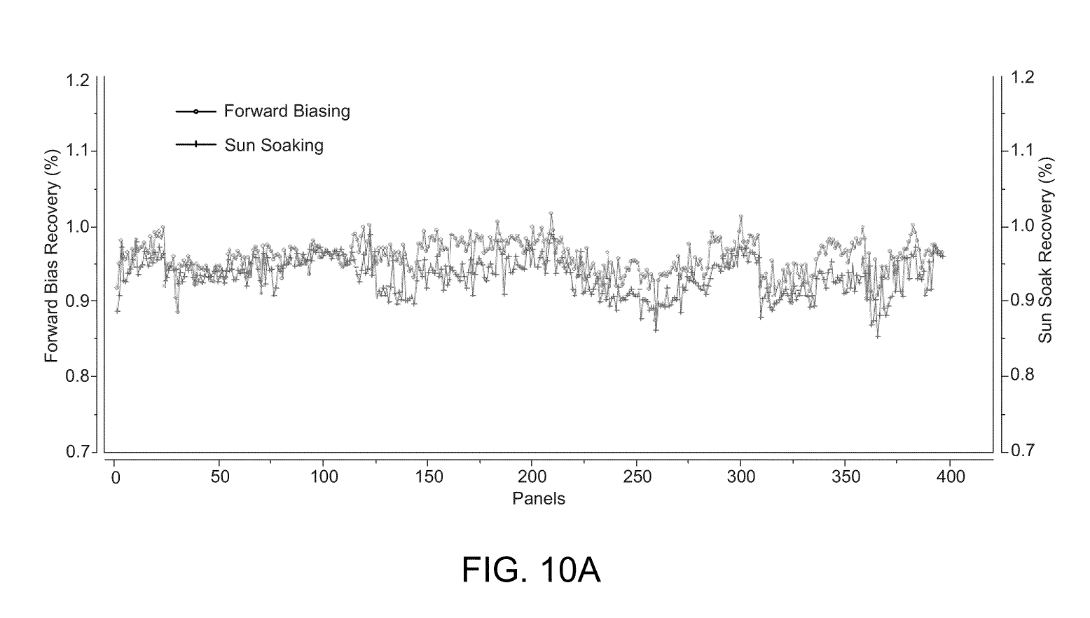

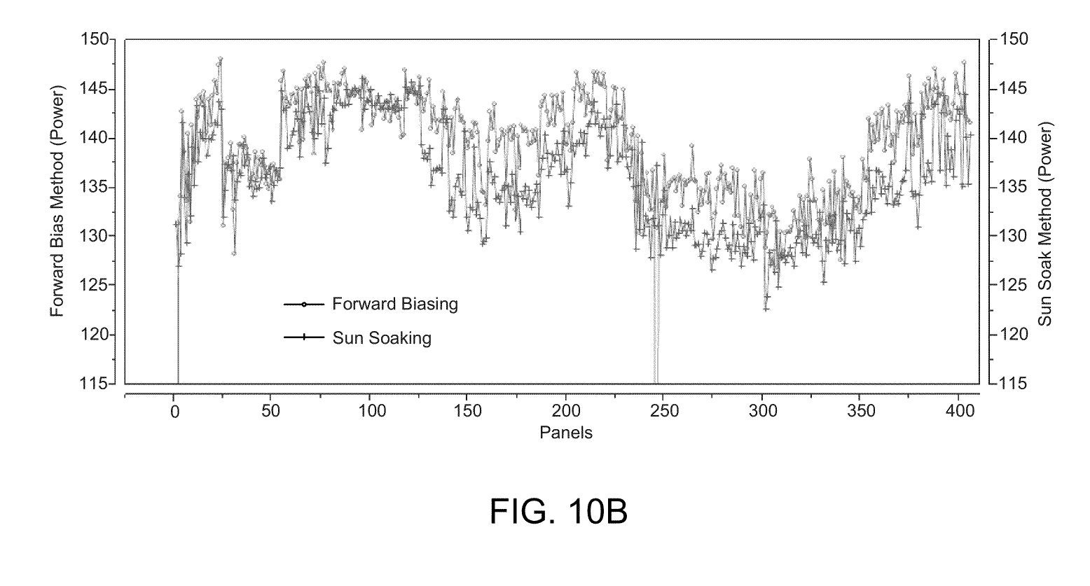

FIGS. 10A and 10B are diagrams showing effectiveness of forward biasing versus sun soaking as a method for recovering solar panel lamination loss according to an embodiment of the present invention. These diagrams are merely examples, which should not unduly limit the scope of the claims herein. As shown, for total number of 160 panels, the effectiveness of forward biasing treatment after panel lamination process is directly compared with the effectiveness of regular sun soaking treatment after panel lamination process. The forward biasing treatment condition is set to 6 electrical pulses with 185V at 50 Amp for 10 seconds with a 10-second rest period between subsequent pulses. The formal treatment shows systematically about 5% better in recovery percentage to the panel measurement pre lamination (FIG. 10A). In terms of actual power measurement data, the forward biasing treated panel outputs about 10 W or more in maximum power than the sun soaked panel.

CIGS film is typical photovoltaic absorber material used in thin film solar panel. It becomes “resistive” during the panel lamination process. “Resistive” means observation of the change in bulk resistance. This change is not actually material resistance increase but an increase in number of recombination sites/defects. During the application of forward biasing treatment, these recombination sites can be filled or repaired. However this is impacted by any shunting structure existed in the thin-film module including either real physical shunts or poor absorber/junction quality. If there is shunting effect, the majority of the current applied via the forward biasing soak (FBS) treatment will pass through those lower resistance paths instead of going through the absorber for repair the recombination sites. It can be partially mitigated by using larger currents when performing the forward biasing treatment, but this is not really ideal because most of that energy applied is wasted. In a specific embodiment, a short light-emitting diode (LED) soak treatment is performed before the applying current through the solar panel so that a lot of the fast acting transients can be repaired, thus reducing the total resistance of the film. The majority of the remaining defects in the film are then repaired by subsequent forward biasing treatment, which still is much more time-efficient than by using conventional light or sun soaking that needs hours of time. Because of the LED soak treatment prior to the FBS, now more current via FBS treatment can pass through the semiconductor CIGS absorber instead of the conducting shunted areas, to direct contribute for improving the panel performance recovery from the lamination process. Although FBS treatment also does repair or blow out some of shunts, but inserting the LED soak treatment can help to save energy by reducing numbers of FBS pulse as well as possible smaller current values.

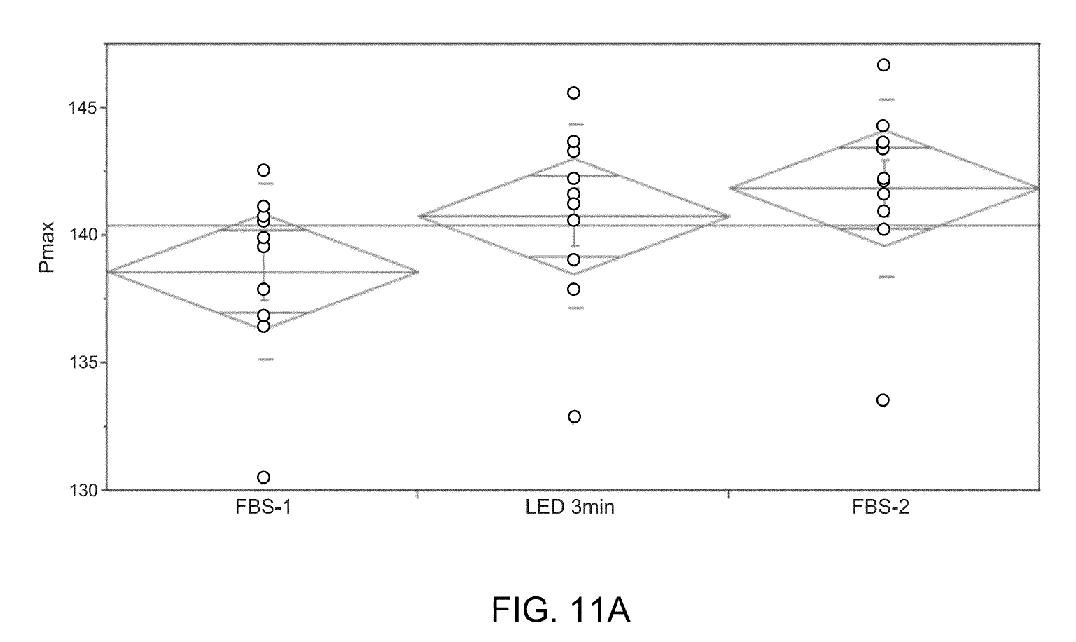

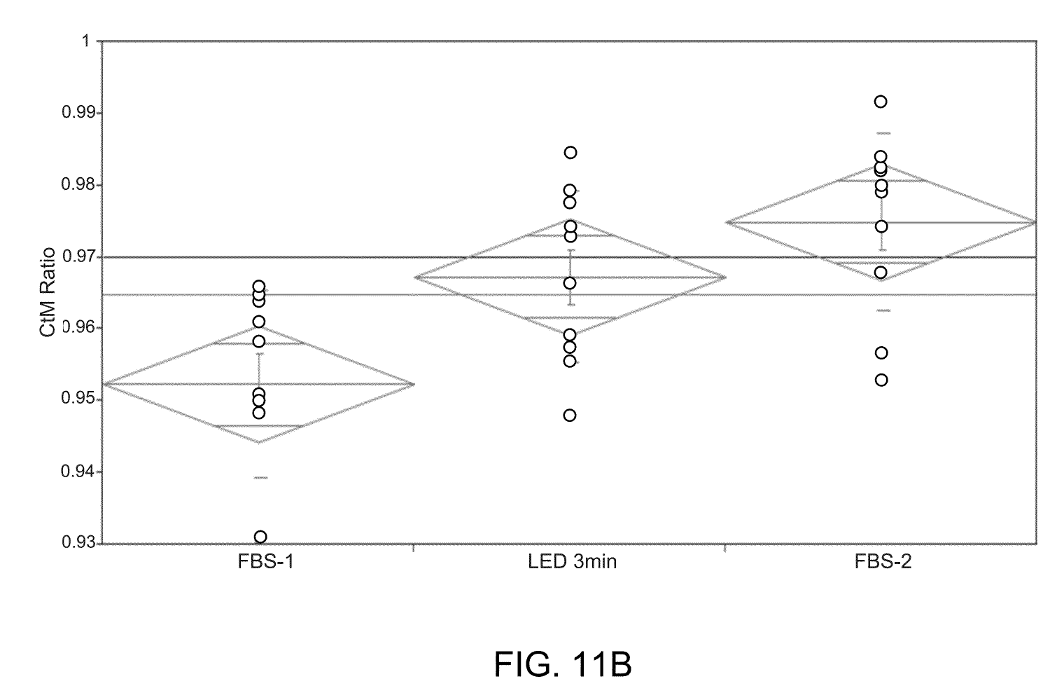

FIGS. 11A and 11B are two diagrams showing effectiveness of using forward biasing with or without a prior LED light soak treatment on panel lamination performance recovery according to a specific embodiment of the present invention. These diagrams are merely examples, which should not unduly limit the scope of the claims herein. As shown in FIG. 11A, maximum output power is used as an indicator of the solar panel performance after lamination. For a first set of data associated with FBS-1, the output power measurements are carried on those laminated solar panels under a forward biasing treatment as suggested above (e.g., several pulses of 50 Amp constant current is applied at 185V). The second set of data is collected from the laminated solar panel that went through a 3 minutes LED light soak treatment before any forward biasing treatment. The third set of data entitled “FBS-2” is obtained by applying the 3-min LED light soak treatment followed by a FBS treatment. It shows the output power values, within certain measurement/production error, are steadily increased. FIG. 11B shows, based on those measurements, comparison results of cell circuit current to module current ratio under the same three conditions. Again, it clearly indicates that the solar panel performance recovery is solid and better for the condition with a LED light soak treatment prior to a FBS treatment than just a FBS treatment alone.

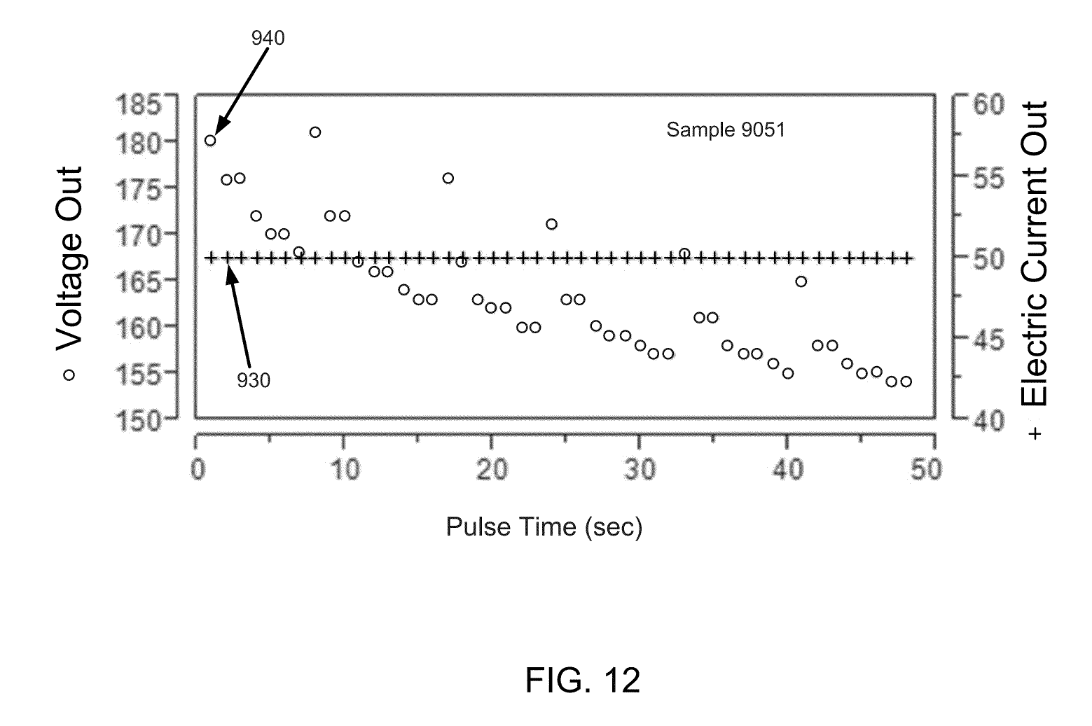

FIG. 12 is a diagram of an electrical biasing I-V profile applied on two thin-film solar panels with a prior 5-min. LED light soak treatment according to an embodiment of the present invention. This diagram is merely an example, which should not unduly limit the scope of the claims herein. As shown, respectively for each thin-film solar panel a pulsed forward bias is applied to two electrodes across the p-n junctions of all cells within the panel based on a proposed procedure as specified below. For the sample 9051, which is a laminated solar panel after a 5-min LED light soak treatment, the forward biasing treatment starts with a first pulse using a power supply in constant current mode, a bias voltage 940 set to maximum value of 185 V and a current 930 value directly reaches the designed maximum 50 Amp value from the start. This is drastically different from that when treating the laminated solar panel without prior LED light soak treatment (see FIG. 9). During the rest of the pulse time of 10 seconds, the biasing voltage 940 actually does not need 185 V, instead of a lower value of 170 V or lower, while the current 930 can be held at the constant value of 50 Amp. Then a rest period of 10-30 seconds takes place, both the current 930 and bias voltage 940 will drop to zero (but are not shown in the plot) before a second pulse (10 sec.) is applied. Every later pulse is following the similar cycle with the required bias voltage 940 starting a peak value smaller than 185 V and ending with a lower value and a lower value about 155 V for keeping the current value 930 at substantially constant 50 Amp value. Each pulse is followed with a rest time ranging from 10 seconds to 30 seconds and total number of pulses can be 5, 6, or up to 10 depending on embodiments. With a prior LED light soak treatment (even for just 5-minutes) before biasing, lower final voltages are enough to achieve 50 Amp current level and no ramping of current is necessary, indicating that the biasing is more effective for repairing the recombination defects within the absorber material instead of being wasted in the shunts conduction.

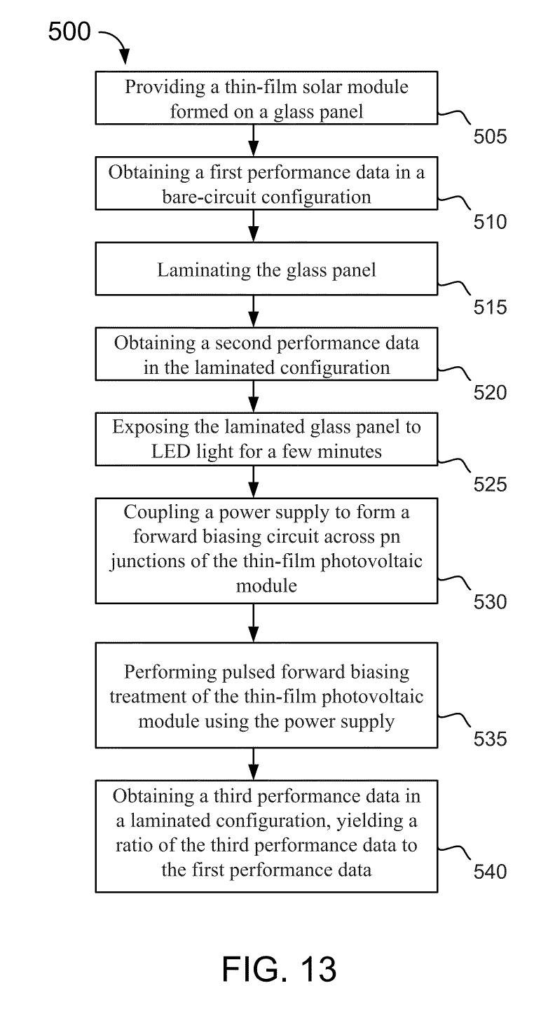

In an embodiment, the present invention provides a method for enhancing and stabilizing photovoltaic performance of a thin-film solar panel after lamination process. FIG. 13 shows a chart that illustrates a series of steps of the method 500 for treating a laminated thin-film solar panel according to an embodiment. In an implementation of the method 500, a thin-film solar module is formed on a glass panel (step 505). For example, the thin-film solar module is provided by Stion Corporation in San Jose, including a plurality of stripe shaped photovoltaic cells arranged in parallel on a 65 cm×165 cm glass panel. The next step (510) of the method 500 is to perform a module measurement to obtain a first set of performance data for all the cells in the bare circuit configuration on the glass panel. The measurement includes IV characteristic measurement for each cell and the module under open circuit and close circuit conditions, from which the maximum output power is obtained. The thin-film solar module is then subjected to a lamination process (step 515) to add frame to the glass panel and have all electric leads of the photovoltaic cells connected to a pair of external electric leads that are located on the back plane of the module.

As shown in FIG. 13, after lamination, a second set of performance data is obtained by measuring the IV characteristic for the solar module in the laminated configuration (step 520). This set of data may show that the lamination process indeed causes some degree of degradation in the photovoltaic efficiency and maximum output power, which has been known conventionally and a main reason that after-lamination sunlight soaking treatment for hours was needed. In an embodiment, for treating the thin-film solar module after lamination for recovering the partial degradation of photovoltaic performance level mentioned above while replacing the inefficient sunlight soak process, the method 500 firstly introduces a next step 525 to expose the laminated thin-film solar panel to the illumination flux of LED light. In additional embodiments the process may include a UV treatment explained in detail below that occurs prior to the LED light treatment, and may occur directly after or within a period of time after the lamination process occurs. An array of LED emitter devices is arranged in a 2D plane sufficiently large for illuminating the whole thin-film solar module framed in 65×165 cm rectangular form factor. In one embodiment, the laminated solar module is stationary in the illumination flux for a predetermined time period. In another embodiment, the laminated solar module is moved along a conveyer while being exposed to the LED light for a predetermined time period. The solar panel can move continuously to pass over the exposure section of the conveyor, or if necessary, stop at the specific section for a prolonged exposure before moving further along the conveyer. In a specific embodiment, the LED light exposure is a designated step of LED soak treatment of the laminated solar module. In a specific implementation the exposure time for the whole solar panel is determined to be 3 minutes. In another specific embodiment, the exposure time is determined to be 5 minutes. Of course, there are variations in LED emitter devices and modifications in specifications in light intensity and wavelength ranges, which may affect the exposure time. Nevertheless, the LED soak treatment process is much shorter in exposure time than conventional sunlight soak process.

Subsequently at step 530, the thin-film solar panel is coupled with a power supply that is configured to form a forward biasing circuit across all pn junctions of the photovoltaic cells associated with the laminated thin-film solar module. In one embodiment, multiple thin-film solar panels are stationed together in a biasing chamber where all solar modules have their external electrical leads in j-box retainers being engaged with respective multiple power supplies. Each power supply is configured to provide a constant current to pass through one solar module under a designated bias voltage. In a specific embodiment, the power supply is configured to provide multiple pulses under a constant current mode at a designated voltage level.

Further as shown in FIG. 13, the method 500 includes a next step 535 for performing one or more electrical pulses under a forward biasing condition with the power supply to treat the thin-film photovoltaic module. In a specific embodiment, each pulse of the forward biasing treatment is a pulsed DC current up to 50 Amp under a pre-set voltage level of 185V. In certain embodiments, depending on different panels, first one or two pulsed current level does not reach to the 50 Amp. In certain other embodiments, with prior LED light exposure, all pulsed current level can reach to 50 Amp. In one embodiment, five pulses are applied with each pulse lasts for 10 seconds followed by 10 seconds rest time. In another embodiment, six pulses are applied. In yet another embodiment, 10 pulses are applied. The pulse length and rest time can also vary depending on embodiments. Afterward, the method 500 includes another step 540 to obtain a third set of performance data from the laminated thin-film solar panel. The performance data include at least the maximum module output power based on module I-V characteristic measurement. The third set of performance data then is compared with the first set of performance data, yielding a performance recovery ratio which is an indicator that the laminated thin-film solar panel has recovered its performance lost during the lamination process and whether the performance is stabilized substantially free from further change due to extended sunlight soak afterward.

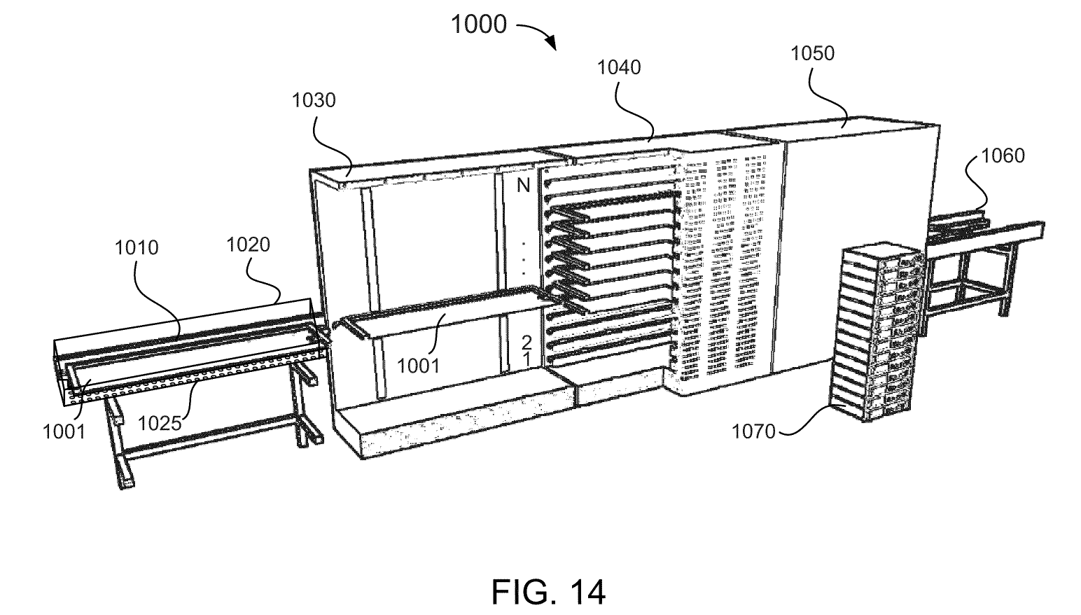

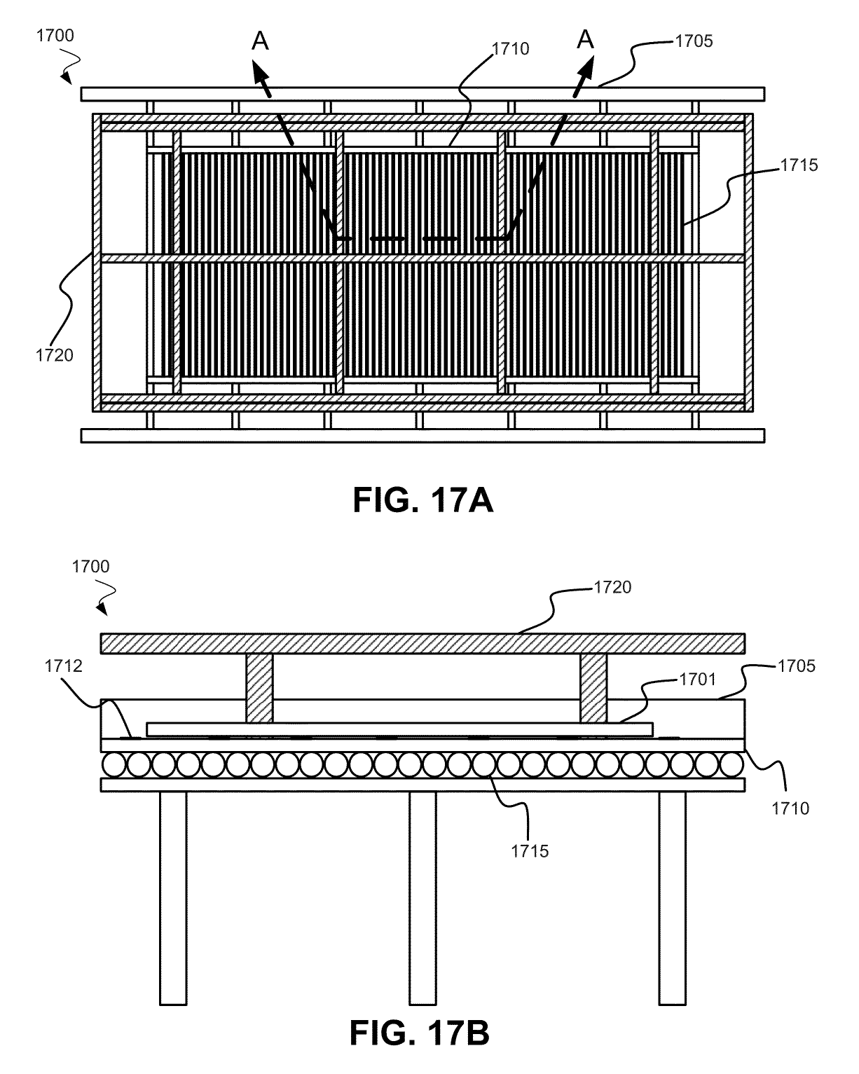

In an alternative embodiment, the present invention also provides an apparatus for treating a group of laminated solar panels for recovering the metastable change of the module performance level for handling large scale volume production of CIGS-based thin-film solar modules. FIG. 14 is a schematic diagram showing an apparatus for after-lamination treatment of a group of monolithic framed thin-film solar modules for performance recovery according to an embodiment of the present invention. This diagram is merely an example, which should not unduly limit the scope of the claims herein. As shown, in an embodiment, the apparatus 1000 is an in-line conveyor based system including a LED light soak station 1020 configured to be fitted into one section of a loading conveyer 1010 for passing one of a plurality of laminated thin-film solar panels 1001. It is to be further understood that an additional UV station (not shown) may be incorporated into the process flow, and the station may resemble the exemplary station illustrated in FIG. 17, for example. In embodiments in which two stations are utilized, the stations may be joined in a number of ways including with a continuing conveyor system between the stations. Additionally, the stations may be separated by a robot or other machinery for transferring substrates between the stations. The UV station may include a plurality of UV lights configured to direct UV light onto a laminated panel prior to the LED light soak station. Such a process is explained in greater detail below.

A forward biasing station 1040 is disposed next to an input elevator station 1030 to receive the laminated solar panel from the LED light soak station 1020 and load multiple solar panels into corresponding one of N slots (named simply as #1 through # N). Within the LED light soak station 1020, a two-dimensional array of LED emitter devices 1025 are disposed for illuminating LED light from below to the thin-film solar panel 1001 transferred by the loading conveyer 1010 at above. The solar panel 1001 is facing down in the loading conveyer 1010 to allow LED light to direct illuminate the absorber material (through transparent window layer and top electrode). Within the forward biasing station 1040, DC current or pulsed DC current can be applied to impose an electrical pulse at certain current level under a forward biasing voltage setting across the p-n junctions of each solar module in laminated form disposed in slots 1 through N.

In an embodiment, the LED light soak station 1020 is an enclosure equipped with a two-dimensional array of LED emitter devices 1025 designated for providing neutral white colored light to illuminate the absorber material of the thin-film solar module faces down. In an implementation, each LED emitter device 1025 is a high luminous efficacy 10 W Neutral White LED element in 7.0 mm×7.0 mm foot print. The relative intensity profile of the LED emitter device is fairly uniform with only 20% drop from 0 to 30 degree angular displacement. The relative spectral power distribution covers substantially all white light wavelength range from about 450 nm to 770 nm. The relative light output is nearly 100% in room temperature range, very convenient for a simple implementation of the LED light soak station 1020 to the in-line conveyer 1010. The length of the LED light soak station 1020 may be determined by overall in-line process time per panel, a so-called TAKT time, for all processes including the LED light soaking treatment, multi-panel loading/unloading, and forward biasing treatment.

As shown in FIG. 14, the in-line system 1000 is configured to move each solar panel 1001 (facing down) onto the load conveyor 1010, then transfer the solar panel into an input elevator 1030 after LED light soak treatment in the LED light soak station 1020, and also after the UV treatment included prior to the LED light soak if used. The input elevator 1030 lowers or rises to match level of an open slot (level 1 through level N) in the biasing station 1040 to dispose the solar module therein. According to the in-line timing design, total N numbers of solar modules are moved into the corresponding N slots in the biasing station 1040 to perform forward biasing treatment at the same time. Each bias chamber slot (1 through N) engages two contacts on the module's j-box retainer (not shown in this scale) using a pneumatic actuator. Circuit continuity will be checked. Then the pulsed DC current is applied under pre-set forward bias voltage from the power supply rack 1070. Based on recipe settings (according to one or more embodiments mentioned throughout the specification and particularly in above sections) the solar panel 1001 is applied with a forward bias targeting either a set-point voltage, current, or time and may repeat multiple (pulsed) biasing steps. After the treatment within the biasing station 1040, an output elevator 1050 then navigates to each slot level and retrieves the biasing-treated module panel. The output elevator 1050 further lowers or rises to match the level of an unloading conveyor 1060, and sends the laminated solar panel 1001 on its way, completing a substantially automatic in-line process.

In another embodiment, the forward biasing station 1040 also is able to determine if a shunt/short or open condition exists within any one module based on analysis of the I-V characteristic of corresponding module. During the biasing treatment stage, the I-V characteristic will be monitored by logging with temperature at 1-second minimum interval using a 4 wire sense system. I-V data monitoring can determine if the particular module is shorted (max I, no V), shunted (high I, low V) or open (no I, max V). In any of these cases, the test is stopped and a “reject” flag is turned on in a control interface. In a specific embodiment, the biasing process condition is set with a maximum voltage 200V, with compliance setting of 0-200V, and maximum current 50 A, with compliance setting of 0-50 A. Biasing time is set to minimum 10 s and maximum 300 s with typical 180 s for multiple pulses with a settable rest time (e.g., 30 sec) in between. The power supply is controlled via a programmable logic controller (PLC) to provide output modulation at 5 seconds ON, 5 seconds OFF minimum cycle with rise/fall rate of is max 10%-90%. The ON/OFF duty cycle is settable from 3%-100%. Modulation cycle time is settable from 10 s up to the full length of the process cycle.

In yet another embodiment, the in-line system 1000 includes further a cooling sub-system for keeping the modules cool during the biasing treatment. In a specific embodiment, the cooling sub-system is a fan based system, moving air across the biasing station 1040, in an approximate laminar flow method, thereby exhausting the warm air out. The output elevator 1050 and/or unloading conveyor 1060 can also be used to provide additional cooling for the solar panel. Temperature control in association with the cooling sub-system should be able to be independently varied and controlled accurately from 10° C. above room temperature to 100% of their maximum temperature. In a specific embodiment, maximum incoming temperature is set to typical 22° C. (<30° C.). Maximum exiting temperature is preferred to be 25° C. (<35° C.). Maximum allowable temperature during biasing is controlled to be about 50° C. or lower.

One design feature of the in-line system 1000 is its throughput of the production line. In an embodiment, the production line is designed for nominal 30 sec panel-to-panel Takt time (without counting the time for LED light soaking) including conveyance, setup and execution of all process steps. The in-line system 1000 is capable of running at any Takt time longer than 30 seconds if necessary, for example, when the LED light soaking is added within the in-line transport conveyor directly. But it at least is designed to run a minimum Takt time of 24 sec. The Takt time should be achievable while the apparatus of the present invention is integrated into its relative position in the whole production line for manufacturing thin-film solar modules. In order to match conveyor speeds into and out of an apparatus with upstream and downstream tool conveyors all in-feed and out-feed conveyors will be independently and continuously adjustable.

In another embodiment, Human-machine interface (HMI) and tool controls are provided for the in-line system 1000 to allow operation from either side of the conveyor line and process stations. The operation modes of the in-line system 1000 include 1) Auto Mode, 2) Manual Mode, 3) Maintenance Mode, and 4) Bypass Mode. Specifically, the Auto Mode is the normal mode of the in-line system 1000 for continuous unattended processing of solar panels via automated interaction with the upstream and downstream tools. The in-line system 1000 would automatically interact with the upstream tool to receive each panel, process the panel, and transfer the next to downstream tool. Once the in-line system 1000 is in operation and all process starting conditions are satisfied, the in-line system 1000 is set to auto mode with a valid recipe so that the continuous processing of multiple products is expected to proceed without operator intervention. If the in-line system 1000 is processing product and is requested (by an operator) to go off-line, the in-line system 1000 shall complete the current process in the normal fashion and convey the product out before going off-line. An indicator shall inform the operator that the in-line system 1000 is still in process while waiting to go offline.

Alternatively, the Manual Mode allows an operator to limit processing to a single run requiring operator initiation. The operator would interact with the in-line system 1000 via the local HMI screen. This mode would generally be used for testing tool process functionality during commissioning, qualification, or service. The Maintenance Mode is intended to allow maintenance and engineering personnel the capability to individually manipulate hardware (such as valves, pumps, MFCs, etc.) for commissioning, servicing, and testing purposes. Further, the Bypass Mode allows the apparatus to be able to feed in, process or bypass, and feed out solar modules with any (or no) layers deposited, including blank glass.

In a specific embodiment, the in-line system 1000 shall be controlled by a PLC controller. All inputs and outputs (I/O), sequencing, SCADA communication and SMEMA interface to adjacent tools or load/unload conveyors shall be controlled by the PLC; Rockwell/A-B PLC is required. All communication with the SCADA system shall be performed by the PLC via an Ethernet/IP (Ethernet Industrial Protocol) port and software on the PLC. Since this is one of many tools on the factory network for manufacturing thin-film solar modules, in order to limit total network traffic this Ethernet/IP port cannot be shared with other I/O on the in-line system 1000. The same port may be used for SCADA, and HMI communications only.

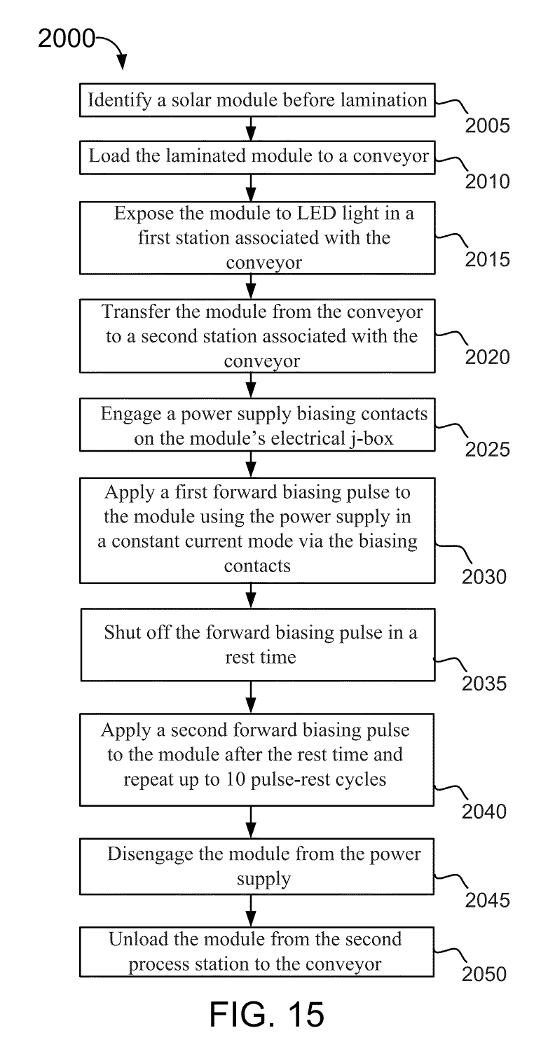

FIG. 15 is chart showing a method for using the in-line system 1000 (of FIG. 14) to treat after-lamination thin-film solar panels for recovering and stabilizing module performance according to an alternative embodiment of the present invention. This diagram is merely an example, which should not unduly limit the scope of the claims herein. As shown, a method 2000 for treating the laminated thin-film solar panels with pulsed biasing in the in-line system 1000 includes the following process steps:

Step 2005: Indentify a module after lamination.
Step 2010: Load the module to a conveyor.
Step 2015: Expose the module to LED light in a first station associated with the conveyor.
Step 2020: Transfer the module from the conveyor to a second station associated with the conveyor.
Step 2025: Engage a power supply biasing contacts on the module's electrical j-box.
Step 2030: Apply a first forward biasing pulse to the module using the power supply in a constant current mode via the biasing contacts.
Step 2035: Shut off the forward biasing pulse in a rest time.
Step 2040: Apply a second forward biasing pulse to the module after the rest time and repeat up to 10 pulse-rest cycles.
Step 2045: Disengage the module from the power supply.
Step 2050: Unload the module from the second process station to the conveyor.

In an embodiment, the step 2005 of indentifying a solar module before a lamination process is performed with this module. The indentifying step includes characterization of the solar module formed on a glass panel by measuring its bare circuit I-V profile at open circuit condition and closed circuit condition. Maximum output power of the solar module can be obtained. After the measurement, the identifying step is followed with a standard glass panel lamination process to add frame and couple a j-box for hooking the module external electrical leads therein. The electrical j-box usually is mounted on the back side of the laminated solar panel. After the lamination process, the framed solar panel is loaded on a moving conveyor in step 2010 of the method 2000. The conveyor is part of an in-line system (1000 in FIG. 14) designed to treat the laminated solar panel for recovering its photovoltaic performance loss during the lamination process. The conveyor is a linear transport device configured to move a plurality of glass panels one after another at a predetermined speed depending on a processing time designated for the upcoming treatment of these panels. In embodiments a UV treatment may be performed subsequent the lamination process. The UV treatment may be optional, performed in lieu of, or in conjunction with the LED soak explained below. The UV treatment may occur directly after or at some period of time subsequent the lamination process.

In a specific embodiment, the laminated solar panel is loaded in a configuration with its front side facing down on the conveyor. As shown in FIG. 14, the conveyor 1010 includes a section being added with a first process station (i.e., LED light soak station 1020) configured to an enclosure where entire bottom plane is provided with array of LED emitter devices 1025. As the loaded solar module in the form of the framed glass panel 1001 is passed by with its front side comprising a photovoltaic absorber material overlaid by a transparent conductive window layer facing down towards the array of LED emitter devices 1025, the photovoltaic absorber material of the whole glass panel 1001 is exposed (step 2015) to the illumination flux of the LED emitter devices 1025 for a predetermined period of time depending on conveyor moving speed. This corresponds to a LED light soak treatment of the laminated solar module to repair a lot of fast acting transients within the absorber material after the lamination process, thus reducing the total resistance of the absorber film. With a reduced film resistance, when the forward biasing is applied, the electrical current would not be forced to flow through those conductive shunts only to waist the electrical biasing pulse power (at least for first few pulses). In a specific embodiment, the LED light exposure time is 3 minutes. In another specific embodiment, the LED light exposure time is 5 minutes. If a UV treatment is performed, the LED light exposure may occur directly after or at some period of time subsequent the exposure process.

As shown in FIG. 15, the method 2000 further includes a step 2020 of transferring the framed solar panel from the conveyor (or the first process station associated with the conveyor) to a second process station associated with the conveyor. In a specific embodiment, for example in FIG. 14, the in-line system 1000 includes an elevator 1030 coupled to the conveyor 1010 or the first process station 1020 for receiving a framed solar panel 1001 and rising or lowering to a selected height to be level with a particular slot (#1, . . . #N) of the second process station 1040. Again, the loading (as well as upcoming unloading) time of a module via the elevator and the total number (N) of the slots in the second process station are limited by the designated process time for this module in the second process station.

Once each framed solar panel is disposed in corresponding slot, electrical contacts of a power supply are engaged with the module's electrical leads in a j-box located on the back side (facing up) of the framed panel. This is the step 2025 of method 200. The power supply is one of a plurality of power supplies respectively associated with particular one of slots #1 through #N and is separately installed in a rack system (for example, rack 1070) next to the second process station 1040.

In a specific embodiment of the method 2000, in the step 2030, one solar panel, after being laminated, exposed to LED light, and now disposed in a particular slot is subjected to an application of a first electrical pulse provided by the power supply configured in a constant current mode. For example, 50 Amp is a set current value through the electrodes in the j-box of the solar panel, and the power supply is designed to allow the maximum bias voltage of about 185 V to achieve this current value. When the first pulse is applied for 10 seconds, in first few seconds, the voltage is usually at the highest value which is 185 V or lower. The voltage value drops slightly to 160 V or lower as time goes by. At the end of the 10 seconds pulse time, the power supply is turned off in step 2035 to start a rest time, all the voltage and current values become zero. The rest time can be set to 10 seconds, 20 seconds, or 30 seconds or others. The first pulse plus the rest time becomes a single cycle of a biasing treatment process. Subsequently, the method 2000 includes step 2040 of applying a second electrical pulse after the rest time. The second pulse is substantially the same as the first pulse. The second pulse is followed with another rest time, forming a second cycle. In an embodiment, during the second cycle, the starting voltage may be lower than the starting voltage used in the first pulse to achieve the current at designated 50 Amp value. Again, the voltage value drops slightly to about 155 V as pulse time lasts for 10 seconds while the current is kept at the constant 50 Amp value through the 10 seconds pulse time. It is then followed by another rest time of 10 seconds, or 20 seconds, or 30 seconds, depending on embodiments. In a specific embodiment, the total number of cycles applying the forward bias through the solar panel is 5 cycles or more, 6 cycles or more, or 10 cycles or more, depending on embodiments. The total biasing process time is still substantially short comparing to hours of conventional sun light soaking treatment. In another specific embodiment, the biasing treatment of each solar panel in each slot of the second process station is substantially independent from each other so that the effective biasing treatment time can be consistent with the total number N of slots, the desired LED light soak treatment time in the first process station (assuming it is set in the part of the in-line system), and corresponding conveyor transport speed and elevator navigate time to determine an optimum panel-to-panel Takt time for the overall process associated with the in-line system.

For each solar panel under the biasing process in a slot of the second process station, once the desired number of bias pulses are all applied, the associated power supply is disengaged its biasing contacts from the electrical leads in the j-box of the corresponding solar panel in the step 2045. Then this solar panel is finished with the biasing treatment and ready for performing step 2050 of the method to unload it from the second process station to the conveyor. In a specific embodiment, the in-line system includes another elevator associated with both the second process station and the conveyor to rise and lower to an identified level where the solar panel is ready. After picking up the identified solar panel, the elevator is re-leveled with the conveyor to unload the panel there, delivering the treated module for testing and other evaluations.

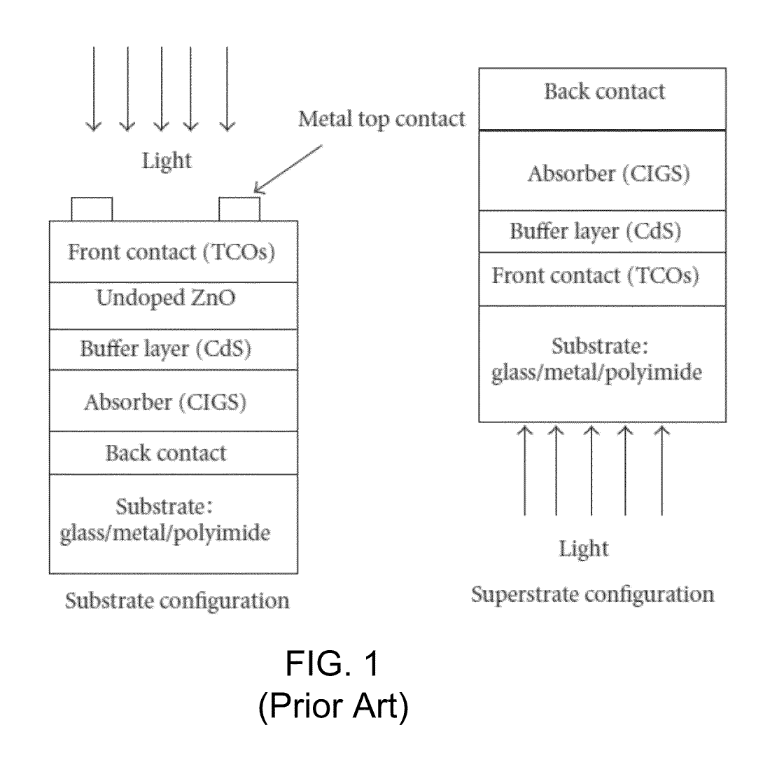

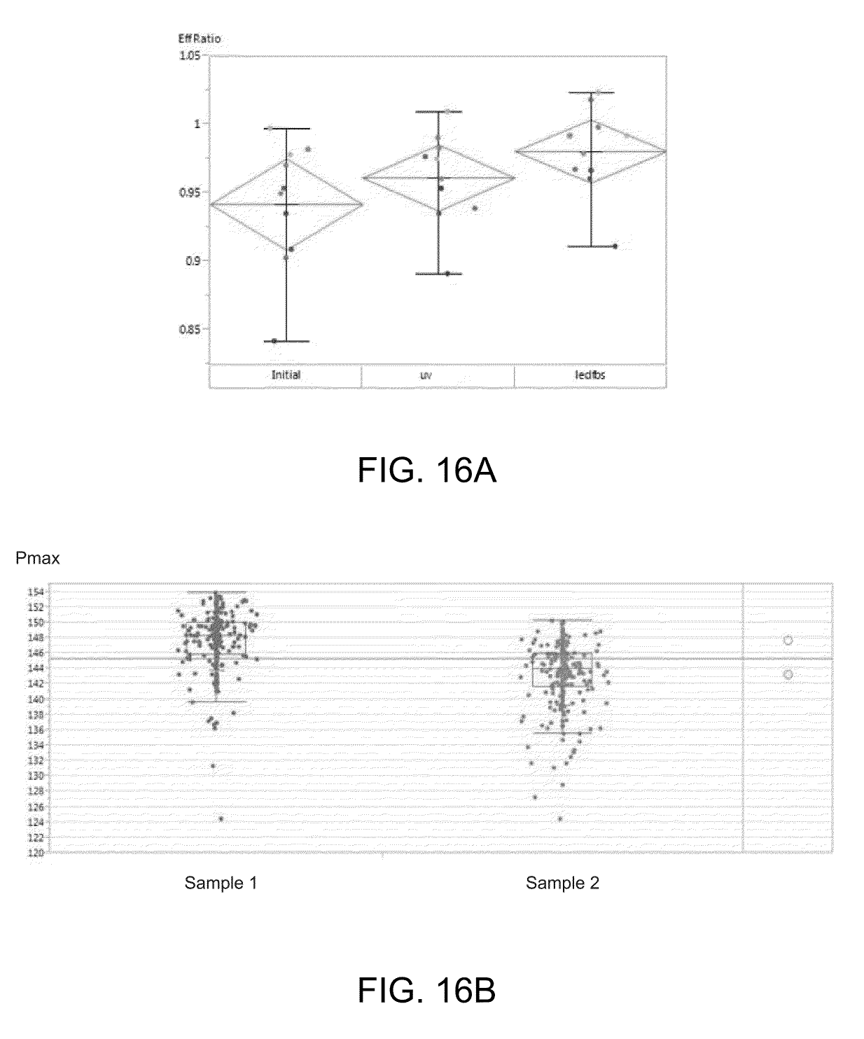

FIG. 16A displays a graph illustrating the effects of a UV light soak treatment that is performed prior to or subsequent to the previously described LED light treatment. The UV light treatment may be performed in an enclosure similar to that described for the LED light treatment, or an alternate chamber including light protection against UV exposure. The UV light station may include an enclosure, or an in-line station equipped with one or more UV lamps. In embodiments, the UV station may include a protective shield about the UV lamps to help minimize or eliminate UV exposure to surrounding personnel. The station may include an array of two or three-dimensionally spaced lamps or bulbs configured to illuminate the substrate and formed layers from the top or bottom. In embodiments, the substrate may be delivered to the UV station with the front contact side up to receive the UV treatment. For example, the window layer, or the ZnO layer as illustrated in FIG. 1, for example, may be at a lesser relative distance to the UV treatment array than the absorber layer. The UV treatment may be delivered to the window layer in a constant or varying power treatment.

For example, light provided in a wavelength from about 450 nm to 10 nm, and in embodiments from below 400 nm, between 400 nm and 350 nm, or below 350 nm, may be delivered to the solar cell, and more specifically to the window layer. Similar to the LED station, the length of the UV light soak treatment may be determined by the overall in-line process time per panel, as well as the speed of the conveyor or system delivering the panels through or to the UV treatment. The UV lamps or bulbs may be a variety of configurations configured to deliver UVA, UVB, and/or UVC light to the panel. In embodiments the amount of UVA light may be greater than or equal to 50%, 75%, 85%, 90%, 95%, 99% or greater with UVB and/or UVC encompassing the difference. The lights may be powered with about or less than 50 Watts, up to, between, or greater than 2,000 Watts or more, including between about 80 Watts and 200 Watts, or greater than 250 Watts, and may include low pressure or high pressure bulbs in embodiments. The lights may include one or more UVB and/or UVC filters, and may provide greater than or about 5, 10, 20, or more times the intensity of full sunlight in individual or multiple UV spectrum bands.

Without being bound by any particular mechanism, the UV treatment may improve the electrical properties of the window layer as well as the quality of the window layer, which may overcome or at least partially overcome the losses explained previously. The treatment may provide an improvement to the window layer, while the LED treatment, which may be performed from the opposite side of the cell or from the same side of the cell through the transparent window and top contact layer, may improve the qualities or electrical properties of the absorber layer. For example, the LED treatment may generate electron-hole pairs which recombine, improving absorber quality as well as injecting electrons and holes. The two treatments may be additive providing an overall benefit to the cell quality and/or performance.

As illustrated in FIG. 16A, after losses are recognized from a lamination process, a UV treatment may be performed prior to an LED treatment. After the LED treatment is performed, the losses may be partially, substantially, or completely overcome in embodiments. The efficiency ratio is graphed along the Y-axis illustrating that the UV treatment may improve overall device efficiency after a certain period of treatment. The improvement may include improvements within the window layer of the device. The treatment may last from a few seconds to over an hour or more. In embodiments, the UV light treatment may last from less than, greater than, or equal to 60 minutes, 45 minutes, 30 minutes, 15 minutes, 10 minutes, 7 minutes, 5 minutes, 3 minutes, 2 minutes, 1 minute, 30 seconds, etc. or less. An additional LED light treatment may be performed which may improve overall device efficiency, and may include improvements within the absorber layer of the device. In conjunction, the benefits afforded by the UV and LED treatments may substantially or completely compensate for the losses associated with a lamination process as explained previously.

FIG. 16B illustrates two sample sets of devices in which the UV treatment as incorporated within the previously identified process flow may improve overall device efficiency. The chart illustrates the overall cell rated power in Watts. The Sample 1 set as illustrated provides overall power improvements over the Sample 2 set, which did not include the UV light soak treatment. As shown, a UV treatment either alone or in conjunction with an LED light treatment may improve overall device efficiency and power. Accordingly, by utilizing a UV and LED light treatment as described herein, losses from lamination may be overcome in drastically reduced time as compared to conventional techniques.

Turning to FIGS. 17A and 17B are shown exemplary UV light soak stations according to embodiments of the present technology. It is to be understood that these figures are not to scale, and are designed to illustrate one concept of a UV station, although any number of modifications may be made to afford improved movement and protection, for example, as will be explained herein. FIG. 17A shows a top view of an exemplary UV light soak station structure 1700, and FIG. 17B shows a partial side view along line A-A. As illustrated, the apparatus includes a structure 1705 supporting a conveyor and series of UV lamps or modules. The UV lamps 1715 may be contained in a grid 1710, which may support a photovoltaic module or substrate for processing. The apparatus may be static or include a conveyor system (not shown) that may allow a substrate to be transported across the apparatus while being exposed to the UV lamps 1715. The UV lamps themselves may be any of the type described above, and may be operated in any of the ways previously described. The conveyor may be above or below the position of the substrate for transporting the substrate, and may be coupled with the sides of the grid 1710 in order to prevent or aid in the prevention of blocking active material deposited on the substrate from being exposed to the UV lamps. Grid 1710 may include feet, or a belt 1712 as illustrated that rotate about grid 1710 transporting a substrate along the apparatus while minimizing blocking any active area to maximize UV exposure to the device.

The substrate 1701 may be positioned on the assembly exposing either the front or backside of the substrate or deposited materials to be facing the UV lamps. In one embodiment, a formed cell may be positioned so the light-receiving or front side is directly receiving the UV exposure. For example, considering the exemplary structure of FIG. 1, the cell may be placed front side down, with the substrate being the furthest layer from the UV lamps. The UV lamps may be positioned in contact with each other, spaced out laterally along grid 1710, or positioned in some orientation to provide consistent light exposure across a substrate being directed against the lamps. As illustrated, lamps 1715 may be tubular lamps positioned directly or substantially in contact with one another or next to one another in a two-dimensional array. The lamps may be of any size or dimensions, but may be configured to light large photovoltaic substrates in embodiments. For example, the lamps 1715 may be at least 50 cm long, and may be at least 60 cm, 75 cm, 80 cm, 100 cm, 120 cm, 150 cm, etc. or more in order to provide sufficient exposure to one or more substrates being delivered across the apparatus. The number of bulbs included in the apparatus may also be variable based on a time of transportation across the structure and/or size of the substrate. For example, the apparatus may include up to or at least 10 UV lamps, and may include up to or greater than 20, 30, 40, 50, 60, 70, 80, 90, 100, etc. or more.

UV exposure apparatus 1700 may also include a structure 1720 built up or around the UV lamps and configured to support a shield device to provide protection from UV exposure. For example, structure 1720 may support a solid sheet material or shell above the UV lamps as well as along the sides by structure 1720. Such a structure may allow protection for personnel who would otherwise be exposed to the UV. Additionally, shield 1720 may be the structure as shown, and a fabric, sheathing, or other UV protective material may be provided about the structure. The material may be flexible or rigid, and may include portions extending towards the front and back of the grid 1710 to provide protection from all directions. The material in front may be flexible and may be in the form of flaps that may be moved for placing and removing a substrate from the apparatus, or may part when a substrate arrives by or with a conveyor mechanism. As illustrated, the shield structure extends laterally past the UV grid on all sides in order to support a shield that protects against exposure from any direction depending on the embodiment. UV station 1700 may be positioned directly in line with LED light soak station 1020 such that a conveyor may deliver a substrate or substrates from the UV station to the LED station without further intervention. The LED and UV stations may have the light systems both be below the front-side down substrate. While the LED station is configured to provide light to the absorber layer, because the front contact and window layer are transparent, the UV and LED treatments may both be performed from this direction. Accordingly, in one example, the UV station as illustrated may deliver a substrate to an LED light soak station in which the LED array is positioned below the substrate, as the substrate may be inverted for the UV treatment. The conveyor system may be coupled between the two stations so that a substrate may be directly delivered from the UV station to the LED station in embodiments along the conveyor.

It is also understood that the examples, figures, and embodiments described herein are for illustrative purposes only and that various modifications or changes in light thereof will be suggested to persons skilled in the art and are to be included within the spirit and purview of this application and scope of the appended claims. Further details of the method for performing a pulsed biasing treatment of thin-film solar modules to recover and stabilize lost module performance during lamination can be found throughout the present specification.

What is claimed is:

1. A method for recovering and stabilizing output power of a thin-film solar module after lamination, the method comprising:
providing a thin-film solar module in a bare-circuit configuration formed on a front side of a glass panel;
obtaining a first performance data associated with the thin-film solar module in the bare-circuit configuration;
laminating the glass panel into a frame to form a thin-film solar module in a laminated configuration with a j-box containing two electrical leads of the thin-film solar module mounted on a back side of the glass panel;
obtaining a second performance data associated with the thin-film solar module in the laminated configuration;
exposing the front side of the laminated glass panel to LED light for a first predetermined time;
coupling a power supply with the two electrical leads to form a bias circuit through the thin-film solar module in the laminated configuration;
performing multiple cycles of a forward biasing treatment via the bias circuit to the thin-film solar module in the laminated configuration, each cycle starting with using the power supply to apply a forward bias voltage sufficient to yield a current at a set value substantially free from current ramping while adjusting the forward bias voltage to keep the current to be constant at the set value till a second predetermined time followed by turning off the power supply for a third predetermined time; and
obtaining a third performance data associated with the thin-film solar module in the laminated configuration after the forward biasing treatment, wherein a ratio of the third performance data over the first performance data is near 1.0 and substantially free from any further change by extended sunlight soak treatment.

2. The method of claim 1 wherein the thin-film solar module comprises a CIGS-based photovoltaic absorber film formed on the front side of the glass panel configured to be a plurality of stripe-shaped cells connected in series.

3. The method of claim 2 wherein laminating the glass panel comprises coupling an electrical input electrode and an output electrode respectively to the two electrical leads in the j-box mounted on the back side of the glass panel.

4. The method of claim 2 wherein exposing the front side of the laminated glass panel comprises allowing the LED light to illuminate the CIGS-based photovoltaic absorber film to repair some recombination sites therein to reduce film resistance.

5. The method of claim 4 wherein exposing the front side of the laminated glass panel comprises passing the laminated glass panel over an array of LED emitter devices each with a 7 mm×7 mm foot print to provide 10 W power of white color luminous flux for soaking corresponding one unit area of the front side of the glass panel for up to 5 minutes.

5. The method of claim 1 wherein coupling the power supply comprises setting the power supply to work under a constant current mode and selecting the current at a set value from a nominal value associated with the bias voltage up to a maximum designed value of the power supply.

6. The method of claim 5 wherein the set value is selected to be 10 Amp or greater.

7. The method of claim 5 wherein the set value is selected to be 38 Amp or greater.

8. The method of claim 5 wherein the set value is selected to be 50 Amp or greater.

9. The method of claim 1 wherein the forward biasing treatment comprises a first cycle by starting the bias voltage at a maximum value allowed by the power supply for yielding the current at the set value, subsequently reducing the bias voltage to just sufficiently large to keep the current at the set value through the bias circuit within the entire second predetermined time ended with turning off the power supply to enter the third predetermined time.

10. The method of claim 9 wherein the forward biasing treatment further comprises one or more cycles after the first cycle, each of the one or more cycles starting with applying the bias voltage just sufficiently large to yield the current at the set value within the entire second predetermined time and ending with turning off the power supply within entire third predetermined time.

11. The method of claim 9 wherein the second predetermined time is about 10 seconds and the third predetermined time is about 10 seconds, or 20 seconds, or 30 seconds.

12. The method of claim 1 wherein performing multiple cycles of forward biasing treatment comprises performing 5 cycles or more.

13. The method of claim 1 wherein performing multiple cycles of forward biasing treatment comprises performing 10 cycles or more.

14. An apparatus for treating a plurality of solar panels after lamination process for recovering and stabilizing photovoltaic performance, the apparatus comprising:
a loading conveyor configured to transfer a plurality of laminated solar panels one after another, each laminated solar panel including a front side formed with a photovoltaic absorber material and a back side mounted with a j-box having two electrical leads;
a first process station enclosing a section of the loading conveyor, the first process station including a 2D array of LED emitter devices disposed across the entire section to provide luminous flux onto the front side of the laminated solar panel passed by;
an input elevator configured to hold one of the plurality of laminated solar panels received from the loading conveyor and navigate multiple height levels from number 1 to number N, N being an integer greater than one;
a second process station comprising multiple slots from number 1 to number N respectively leveled with the corresponding multiple height levels of the input elevator, each slot being configured to receive one laminated solar panel from the input elevator at a time;
a power rack station comprising multiple power supplies, each power supply being configured to couple with the two electrical leads in the j-box of the laminated solar panel loaded in the corresponding one of multiple slots of the second process station and to apply multiple forward bias voltage pulses with constant current through the laminated solar panel;
an output elevator configured to navigate the multiple height levels for picking up one laminated solar panel from the corresponding slot of the second process station; and
an unloading conveyor configured to receive the laminated solar panel from the output elevator and deliver away the laminated solar panel.

15. The apparatus of claim 14 wherein the loading conveyor is a linearly configured to move the laminated solar panel laid flat with the front side facing down.

16. The apparatus of claim 14 wherein the 2D array of LED emitter devices are arranged on a plane substantially covering the entire section of the conveyor enclosed by the first process station wherein the plane being a distance below a loading plane of the conveyor.

17. The apparatus of claim 16 wherein each LED emitter device comprises a 7 mm×7 mm footprint for producing white color luminous flux in about 10 W power projected upward.

18. The apparatus of claim 17 wherein the first process station is configured to allow the photovoltaic absorber material on the front side of the laminated solar panel to be exposed to the white color luminous flux from the LED emitter devices for 5 minutes or less.

19. The apparatus of claim 14 wherein the multiple slots in the second process station are configured to perform a forward biasing treatment to one laminated solar panel at each slot independently with flexibility of partial usage of slot number 1 through N to accommodate a panel-to-panel time for receiving the laminated solar panels from the loading conveyor and navigation time for loading/unloading each laminated solar panel via the input/output elevator.

20. The apparatus of claim 14 wherein each of the multiple power supplies is configured to work in a constant current mode for generating a current at a set value with a bias voltage being applied in a variable range up to a maximum allowed voltage associated with the set value of the current.

21. The apparatus of claim 14 wherein the power supply comprises a programmable logic control unit to control each of the multiple forward bias voltage pulses for providing the current at the set value in a pulse time for about 10 seconds and turning off the current and the bias voltage in a rest time for about 10 to 30 seconds.

22. The apparatus of claim 14 further comprising a human-machine interface for operating the conveyor and the first and the second process stations, the human-machine interface including an Auto Mode, a Manual Mode, a Maintenance Mode, and a Bypass Mode.

23. A method for processing a thin-film solar module after lamination, the method comprising:
loading a thin-film solar module on a conveyor, the thin-film solar module being on a laminated glass panel having a front side formed with a photovoltaic absorber material and a back side mounted with a j-box having two external electrical leads of the thin-film solar module;
moving the laminated glass panel along the conveyor into a first process station having an array of LED emitter devices installed therein;
exposing the photovoltaic absorber material on the entire front side to light provided from the array of LED emitter devices for a first predetermined time as the laminated glass panel continues to move along the conveyor;
transferring the laminated glass panel from the first process station to a loading elevator configured to navigate multiple height levels;
loading the laminated glass panel into a second process station from the loading elevator, the laminated glass panel being disposed in a selected slot that is leveled with one of the multiple height levels of the loading elevator;
coupling a power supply with the two electrical leads in the j-box mounted on the back side of the laminated glass panel in the selected slot to form a bias circuit through the thin-film solar module;
performing multiple cycles of forward biasing treatment to the thin-film solar module via the bias circuit, each cycle starting with using the power supply in a constant current mode to apply a forward bias voltage pulse at a sufficiently large value to yield a current at a desired set value while adjusting the voltage to keep the current to be constant at the desired set value till a second predetermined time followed by turning off the power supply for a third predetermined time; and
unloading the laminated glass panel from the second process station to the conveyor via an unloading elevator capable of navigate the same multiple height levels.

24. A system providing post lamination treatment to a photovoltaic substrate, the system comprising:
a conveyor configured to deliver a substrate from a first light station to a second light station; wherein:
the first light station comprises a plurality of UV light sources positioned below the conveyor system and configured to provide light in a wavelength below about 400 nm to a front side of the photovoltaic device to expose a window layer to the light; and
the second light station comprises a plurality of LED light sources positioned below the conveyor system and configured to provide light in a wavelength above about 400 nm to the front side of the photovoltaic substrate to expose an absorber layer to the LED light.
